(19) United States
(12) Patent Application Publication
(10) Pub. No.: US 2026/0013335 A1
(43) Pub. Date: Jan. 8, 2026

(54) DISPLAY PANEL, MANUFACTURING METHOD FOR THE SAME AND ELECTRONIC DEVICE INCLUDING THE DISPLAY PANEL

(71) Applicant: Samsung Display Co., Ltd., Yongin-si (KR)

(72) Inventors: SUNHO KIM, Yongin-si (KR); YOOMIN KO, Yongin-si (KR); Hyewon KIM, Yongin-si (KR); JUCHAN PARK, Yongin-si (KR); Yerim SON, Yongin-si (KR); PILSUK LEE, Yongin-si (KR); CHUNG SOCK CHOI, Yongin-si (KR); SUNGJIN HONG, Yongin-si (KR)

(21) Appl. No.: 19/258,606

(22) Filed: Jul. 2, 2025

(30) Foreign Application Priority Data
Jul. 4, 2024 (KR) 10-2024-0088071

(51) Int. Cl. H10K 59/122; H10K 59/12; H10K 59/121; H10K 59/131

(52) U.S. Cl. CPC H10K 59/122; H10K 59/1201; H10K 59/1213; H10K 59/131

(57) ABSTRACT

A display panel includes a base layer, a drive element layer that is on the base layer and that includes a pixel driver including a power supply voltage, a conductive pattern at the drive element layer and electrically connected with the power supply voltage, a pixel defining layer that is on the drive element layer and in which a light-emitting opening and a groove that surrounds the light-emitting opening are defined, a light-emitting element that is on the pixel defining layer and that includes a first electrode partially exposed by the light-emitting opening, an intermediate layer on the first electrode, and a second electrode on the intermediate layer and disconnected by the groove, and a connecting electrode between the pixel defining layer and the second electrode and electrically connected with the conductive pattern and the second electrode.

### CROSS-REFERENCE TO RELATED APPLICATION

The present application claims priority to and the benefit of Korean Patent Application No. 10-2024-0088071, filed on Jul. 4, 2024, in the Korean Intellectual Property Office, the entire disclosure of which is incorporated herein by reference.

### BACKGROUND

### 1. Field

Aspects of one or more embodiments of the present disclosure described herein relate to a display panel, a method for manufacturing the display panel, and an electronic device including the display panel. For example, one or more embodiments relate to a display panel with improved display quality.

### 2. Description of the Related Art

A display device, such as a television, a monitor, a smart phone, a tablet computer, and/or the like, provides an image to a user through a display panel (that displays the image). One or more suitable display panels, including liquid crystal display panels, organic light-emitting display panels, electrowetting display panels, electrophoretic display panels, and/or the like, are being developed.

### SUMMARY

Aspects of one or more embodiments of the present disclosure are directed toward a display panel with enhanced (e.g., improved) display quality, a method for manufacturing the display panel, and an electronic device including the display panel.

According to one or more embodiments, a display panel includes a base layer, a drive element layer that is arranged on the base layer and that includes a pixel driver including a power supply voltage, a conductive pattern at (e.g., arranged in) the drive element layer and electrically connected with the power supply voltage, a pixel defining layer that is arranged on the drive element layer and in which a light-emitting opening and a groove that surrounds the light-emitting opening are defined, a light-emitting element that is arranged on the pixel defining layer and that includes a first electrode partially exposed by the light-emitting opening, an intermediate layer arranged on the first electrode, and a second electrode arranged on the intermediate layer and disconnected by the groove, and a connecting electrode arranged between the pixel defining layer and the second electrode and electrically connected with the conductive pattern and the second electrode.

The connecting electrode may include a first edge and a second edge that surrounds the first edge, and the second edge may overlap the groove.

The second electrode and the connecting electrode may be connected in an area adjacent to the groove.

The connecting electrode may include a tip portion that protrudes from an end of the groove, and the second electrode and the connecting electrode may be connected at the tip portion.

The connecting electrode may further include a first connecting electrode layer arranged on the pixel defining layer and a second connecting electrode layer arranged on the first connecting electrode layer, and the second connecting electrode layer may cover the first connecting electrode layer.

The intermediate layer may be arranged on the second connecting electrode layer, and the second electrode may be arranged on the intermediate layer. The second electrode may be connected with the second connecting electrode layer at the tip portion.

A first split pattern including the same material as the second connecting electrode layer, a second split pattern including the same material as the intermediate layer, and a third split pattern including the same material as the second electrode may be arranged at the groove.

The first split pattern may be electrically connected with the third split pattern.

The connecting electrode may further include a first connecting electrode layer arranged on the pixel defining layer. The intermediate layer may cover the first connecting electrode layer, and the second electrode may be connected with the first connecting electrode layer at the tip portion.

A first split pattern including the same material as the intermediate layer and a second split pattern including the same material as the second electrode may be arranged at the groove.

The pixel defining layer may include a first pixel defining layer portion and a second pixel defining layer portion formed on the first pixel defining layer portion. The first pixel defining layer portion may be integrally formed with the second pixel defining layer portion, and the groove may be defined in the second pixel defining layer portion.

A through-hole may be additionally defined at (e.g., in) the pixel defining layer, and the connecting electrode may be connected to the conductive pattern through the through-hole.

The light-emitting element may include a plurality of light-emitting elements, the pixel driver may include a plurality of pixel drivers, the connecting electrode may include a plurality of connecting electrodes, and the plurality of light-emitting elements may include a plurality of second electrodes disconnected from one another. The plurality of second electrodes may be connected to the conductive pattern through the plurality of connecting electrodes, respectively, and the conductive pattern may electrically connect the power supply voltage with the plurality of second electrodes.

A gap between connecting electrodes adjacent to each other among the plurality of connecting electrodes may overlap the groove.

According to one or more embodiments, a method includes preparing a preliminary display panel including a base layer, a drive element layer that is arranged on the base layer and that includes a pixel driver including a power supply voltage, a conductive pattern arranged at the drive element layer and electrically connected with the power supply voltage, and a pixel defining layer arranged on the drive element layer, depositing, on the preliminary display panel, a first connecting electrode layer connected to the conductive pattern, forming a groove of the pixel defining layer that overlaps a portion of the first connecting electrode layer, by etching a portion of the first connecting electrode layer and a portion of the pixel defining layer, forming a connecting electrode by etching the first connecting electrode layer, and forming, on the connecting electrode and the pixel defining layer, an intermediate layer and a cathode connected to the connecting electrode.

The forming of the connecting electrode may include forming a tip portion defined at an end of the first connecting electrode layer.

The forming of the intermediate layer and the cathode connected to the connecting electrode may include depositing a cathode disconnected by the groove and connected with the first connecting electrode layer.

The method may further include depositing a second connecting electrode layer on the first connecting electrode layer and forming a tip portion defined at an end of the first connecting electrode layer and an end of the second connecting electrode layer. The forming of the connecting electrode may include etching the second connecting electrode layer.

The forming of the intermediate layer and the cathode connected to the connecting electrode may include depositing a cathode disconnected by the groove and connected with the second connecting electrode layer.

According to one or more embodiments, an electronic device includes a display panel for providing an image, and a processor to control an operation of the display panel. The display panel includes a base layer, a drive element layer that is arranged on the base layer and that includes a pixel driver including a power supply voltage, a conductive pattern arranged at the drive element layer and electrically connected with the power supply voltage, a pixel defining layer that is arranged on the drive element layer and in which a light-emitting opening and a groove that surrounds the light-emitting opening are defined, a light-emitting element that is arranged on the pixel defining layer and that includes a first electrode partially exposed by the light-emitting opening, an intermediate layer arranged on the first electrode, and a second electrode arranged on the intermediate layer and disconnected by the groove, and a connecting electrode arranged between the pixel defining layer and the second electrode and electrically connected with the conductive pattern and the second electrode.

### BRIEF DESCRIPTION OF THE DRAWINGS

The above and other objects and features of the present disclosure will become apparent by describing in more detail embodiments thereof with reference to the accompanying drawings.

FIG. 1A is a perspective view of a display device according to one or more embodiments of the present disclosure.

FIG. 1B is an exploded perspective view of the display device according to one or more embodiments of the present disclosure.

FIG. 2 is a sectional view of a display module according to one or more embodiments of the present disclosure.

FIG. 3 is a plan view of a display panel according to one or more embodiments of the present disclosure.

FIG. 4 is an equivalent circuit diagram of a pixel according to one or more embodiments of the present disclosure.

FIG. 5 is an enlarged plan view of a partial area of the display panel according to one or more embodiments of the present disclosure.

FIG. 6 is a sectional view of the display panel according to one or more embodiments of the present disclosure.

FIG. 7 is an enlarged sectional view of a partial area of the display panel according to one or more embodiments of the present disclosure.

FIG. 8A is an enlarged plan view of a partial area of the display panel according to one or more embodiments of the present disclosure.

FIG. 8B is an enlarged sectional view of a partial area of the display panel according to one or more embodiments of the present disclosure.

FIGS. 9-11 are enlarged sectional views each showing a partial area of the display panel according to embodiments of the present disclosure.

FIGS. 12A-12F are sectional views illustrating some of the steps (e.g., acts or tasks) of a display panel manufacturing method according to one or more embodiments of the present disclosure.

FIGS. 13A-13C are sectional views illustrating some of the steps (e.g., acts or tasks) of a display panel manufacturing method according to one or more embodiments of the present disclosure.

FIGS. 14A-14F are sectional views illustrating some of the steps (e.g., acts or tasks) of a display panel manufacturing method according to one or more embodiments of the present disclosure.

FIGS. 15A-15C are sectional views illustrating some of the steps (e.g., acts or tasks) of a display panel manufacturing method according to one or more embodiments of the present disclosure.

FIG. 16 is a block diagram of an electronic device, according to one or more embodiments of the present disclosure.

### DETAILED DESCRIPTION

Aspects of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in one or more suitable different forms, and should not be construed as being limited to only the illustrated embodiments herein. Rather, these embodiments are provided as examples so that the present disclosure will be thorough and complete, and will fully convey the aspects of the present disclosure to those skilled in the art. Accordingly, processes, elements, and techniques that are not necessary to those having ordinary skill in the art for a complete understanding of the aspects of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

One or more suitable embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved shapes and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in one or more suitable different ways, all without departing from the spirit or scope of the present disclosure and equivalents thereof.

In the detailed description, for the purposes of explanation, numerous specific details are set forth to provide a thorough understanding of one or more suitable embodiments. It is apparent, however, that one or more suitable embodiments may be practiced without these specific details or with one or more equivalent arrangements. In other instances, well-known structures and devices are shown in block diagram form to avoid unnecessarily obscuring one or more suitable embodiments.

Spatially relative terms, such as “beneath,” “below,” “lower,” “under,” “above,” “upper,” and the like, may be utilized herein for ease of explanation to describe one element's relationship to another element(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements would then be oriented “above” the other elements. Thus, the example terms “below” and “under” can encompass both an orientation of above and below. The device may be otherwise oriented (e.g., rotated 90 degrees or at other orientations) and the spatially relative descriptors utilized herein should be interpreted accordingly. Similarly, if (e.g., when) a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in plan view,” means viewing a target portion from the top, and the phrase “on a cross-section” means viewing a cross-section formed by vertically cutting a target portion from the side.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” and “at least one selected from the group consisting of X, Y, and Z” may be construed as X only, Y only, Z only, any combination of two or more of X, Y, and Z, such as, for instance, XYZ, XY, XZ, and YZ, or any variation thereof. Similarly, the expression such as “at least one of A and B” may include A, B, or A and B. As utilized herein, the term “and/or” includes any and all combinations of one or more of the associated listed items. For example, the expression such as “A and/or B” may include A, B, or A and B.

Further, the use of “may” when describing embodiments of the present disclosure refers to “one or more embodiments of the present disclosure”.

The same reference numerals refer to the same components. Further, in the drawings, the thickness, the ratio, and the dimension of components are exaggerated for effective description of technical contents. The expression “and/or” includes one or more combinations which associated components are capable of defining.

It will be understood that, although the terms “first”, “second”, etc. may be utilized herein to describe one or more suitable components, the components should not be limited by the terms. The terms are only utilized to distinguish one component from another component. For example, without departing from the right scope of the present disclosure, a first component may be referred to as a second component, and similarly, the second component may be also referred to as the first component.

Singular expressions include plural expressions unless clearly otherwise indicated in the context.

In the examples, the DR1-axis, the DR2-axis, and/or the DR3-axis are not limited to three axes of a rectangular coordinate system, and may be interpreted in a broader sense. For example, the DR1-axis, the DR2-axis, and the DR3-axis may be perpendicular to one another, or may represent different directions that are not perpendicular to one another. The same applies for first, second, and/or third directions.

The terminology utilized herein is for the purpose of describing particular embodiments only and is not intended to be limiting of the present disclosure. As utilized herein, the singular forms “a” and “an” are intended to include the plural forms as well, unless the context clearly indicates otherwise.

In the present disclosure, it will be understood that the terms “include/includes/including,” “comprise/comprises/comprising,” or “have/has/having,” specifies the presence of stated features, integers, numbers, steps, operations, elements, and/or components, but do not preclude the presence or addition of one or more other features, integers, numbers, steps, operations, elements, components, and/or groups thereof. Additionally, the terms “include/includes/including,” “comprise/comprises/comprising,” or “have/has/having,” or similar terms include or support the terms “consisting of” and “consisting essentially of,” indicating the presence of stated features, integers, steps, operations, elements, and/or components, without or essentially without precluding the presence or addition of other features, integers, steps, operations, elements, components, and/or groups thereof.

As utilized herein, the term “substantially,” “about,” “approximately,” and similar terms are utilized as terms of approximation and not as terms of degree, and are intended to account for the inherent deviations in measured or calculated values that would be recognized by those of ordinary skill in the art. “About” or “approximately,” as utilized herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Unless otherwise defined, all terms (including technical terms and scientific terms) utilized in the specification have the same meaning as commonly understood by those skilled in the art to which the present disclosure belongs. Further, terms such as terms defined in the dictionaries commonly utilized should be interpreted as having a meaning consistent with the meaning in the context of the related technology and should not be interpreted in overly ideal or overly formal meanings unless explicitly defined herein.

It will be understood that if (e.g., when) a component (e.g., an element, an area, a layer, a part, a portion, a region, and/or the like) is referred to as being “on”, “formed on”, “disposed on”, “connected to”, “connected with”, or “coupled to” another component, this refers to that the component may be directly or indirectly on, formed on, disposed on, connected to, connected with, or coupled to the other component, such that one or more intervening components may be present therebetween. For example, when an element, layer, part, portion, region, or component is referred to as being “electrically connected” or “electrically coupled” to another element, layer, part, portion, region, or component, it can be directly electrically connected or coupled to the other element, layer, part, portion, region, or component, or intervening elements, layers, parts, portions, regions, or components may be present. However, “directly connected/directly coupled” refers to one component directly connecting or coupling another component without any intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

Identical reference numerals refer to substantially identical components. Additionally, in the drawings, the thicknesses, proportions, and dimensions of components are exaggerated for effective description. As utilized herein, the term “and/or” includes all of one or more combinations defined by related components.

Terms such as first, second, and/or the like may be utilized to describe one or more suitable components, but the components should not be limited by the terms. The terms may be utilized only for distinguishing one component from other components. For example, without departing the scope of the present disclosure, a first component may be referred to as a second component, and similarly, the second component may also be referred to as the first component. The terms of a singular form may include plural forms unless otherwise specified.

Unless otherwise defined, all terms utilized herein, including technical or scientific terms, have the same meanings as those generally understood by those skilled in the art to which the present disclosure pertains. Such terms as those defined in a generally utilized dictionary are to be interpreted as having meanings equal to the contextual meanings in the relevant field of art, and are not to be interpreted as having ideal or excessively (or substantially) formal meanings unless clearly defined as having such in the present application.

Hereinafter, display panels in accordance with one or more embodiments of the present disclosure will be described in more detail with reference to the accompanying drawings. The same reference numerals are utilized for the same components in the drawings, and redundant descriptions of the same components will not be provided.

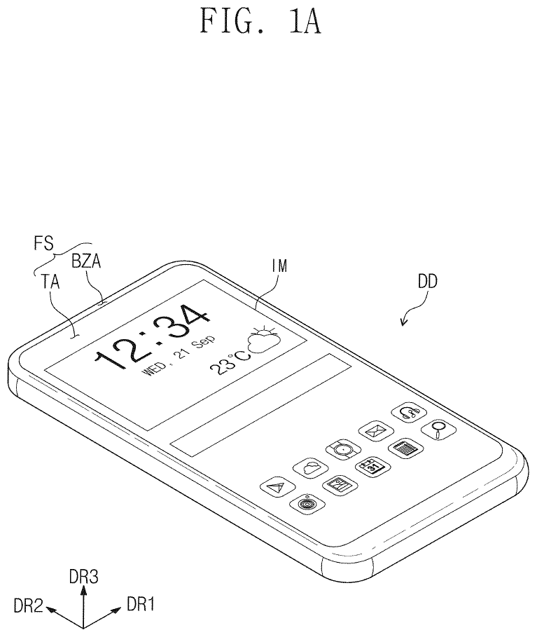

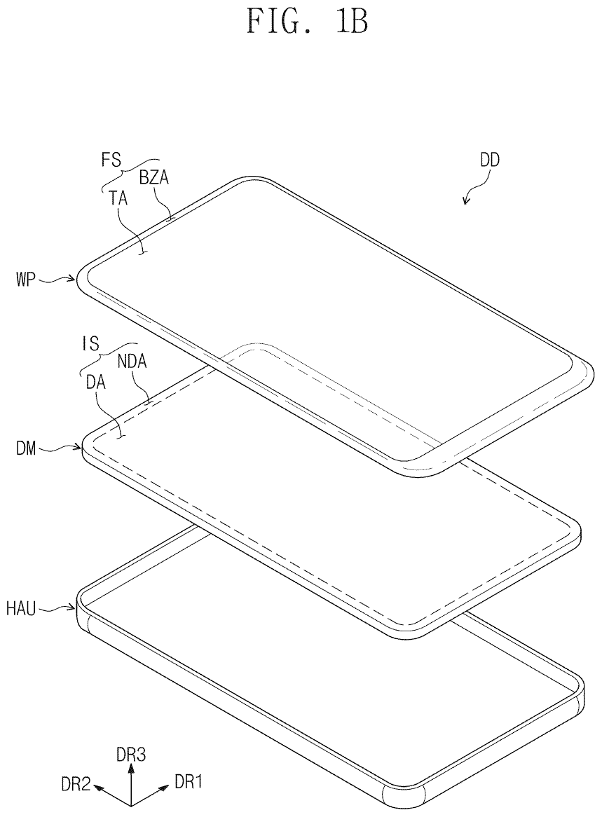

FIG. 1A is a perspective view of a display device DD according to one or more embodiments of the present disclosure. FIG. 1B is an exploded perspective view of the display device DD according to one or more embodiments of the present disclosure.

In one or more embodiments, the display device DD may be a large electronic device such as a television, a monitor, and/or a billboard. In one or more embodiments, the display device DD may be a small and/or medium-sized electronic device, such as a personal computer, a notebook computer, a personal digital terminal, a car navigation unit, a game machine, a smart phone, a tablet computer, and/or a camera. However, this is illustrative, and the display device DD may be employed as other display devices without departing from the spirit and scope of the present disclosure and equivalents thereof. For example, in FIGS. 1A and 1B, the display device DD is illustrated as a smart phone.

Referring to FIGS. 1A and 1B, the display device DD may display an image IM in a third direction DR3 on a display surface FS parallel to a first direction DR1 and a second direction DR2. The image IM may include a still image as well as a dynamic image. In FIG. 1A, a clock window and icons are illustrated as an example of the image IM. The display surface FS on which the image IM is displayed may correspond to the front surface of the display device DD.

In one or more embodiments (e.g., an embodiment of a smart phone), front surfaces (e.g., upper surfaces) and rear surfaces (e.g., lower surfaces) of members are defined based on the direction in which the image IM is displayed. The front surfaces and the rear surfaces may be opposite with each other in the third direction DR3, and the normal directions of the front surfaces and the rear surfaces may be parallel to the third direction DR3. In one or more embodiments, the directions indicated by the first to third directions DR1, DR2, and DR3 may be relative concepts and may be changed to other directions. The expression “if (e.g., when) viewed from above a plane” utilized herein may refer to that it is viewed in the third direction DR3.

The display device DD may include a window WP, a display module DM, and a housing HAU. The window WP and the housing HAU may be coupled with each other to form the exterior of the display device DD.

The window WP may include an optically clear insulating material. For example, the window WP may include glass and/or plastic. The front surface of the window WP may define the display surface FS of the display device DD. The display surface FS may include a transmissive area TA and a bezel area BZA. The transmissive area TA may be an optically clear area. For example, the transmissive area TA may be an area having a visible light transmittance of about 90% or more.

The bezel area BZA may be an area having a lower light transmittance than the transmissive area TA. The bezel area BZA may define the shape of the transmissive area TA. The bezel area BZA may be adjacent to the transmissive area TA and may be around (e.g., surround) the transmissive area TA. However, this is illustrative, and the bezel area BZA of the window WP may not be provided. The window WP may include at least one of an anti-fingerprint layer, a hard coating layer, and/or an anti-reflective layer and is not limited thereto.

The display module DM may be arranged under the window WP. The display module DM may be a component that substantially generates the image IM. The image IM generated by the display module DM may be displayed on a display surface IS of the display module DM and may be visually recognized by a user from the outside through the transmissive area TA.

The display module DM may include a display area DA and a non-display area NDA. The display area DA may be an area activated depending on an electrical signal. The non-display area NDA may be adjacent to the display area DA. The non-display area NDA may be around (e.g., surround) the display area DA. The non-display area NDA may be an area covered by the bezel area BZA and may not be visible from the outside.

The housing HAU may be coupled with the window WP. The housing HAU may be coupled with the window WP to provide an inner space. The display module DM may be accommodated in the inner space.

The housing HAU may include a material having a relatively high rigidity. For example, the housing HAU may include glass, plastic, and/or metal or may include a plurality of frames and/or plates formed of a combination of the aforementioned materials. The housing HAU may stably protect components of the display device DD accommodated in the inner space from external impact.

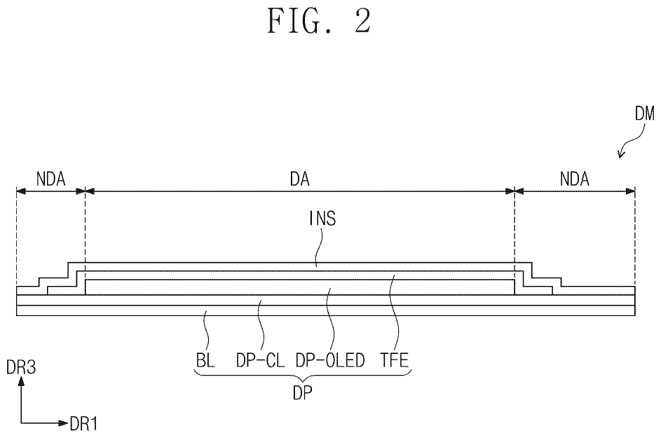

FIG. 2 is a sectional view of the display module DM according to one or more embodiments of the present disclosure.

Referring to FIG. 2, the display module DM may include a display panel DP and an input sensor INS. Although not separately illustrated, the display device DD (refer to FIG. 1A) according to one or more embodiments of the present disclosure may further include a protective member arranged on the lower surface of the display panel DP or an anti-reflective member and/or a window member arranged on the upper surface of the input sensor INS.

The display panel DP may be an emissive display panel. However, this is illustrative, and the present disclosure is not particularly limited thereto. For example, the display panel DP may be an organic light-emitting display panel or an inorganic light-emitting display panel. An emissive layer in the organic light-emitting display panel may include an organic luminescent material. An emissive layer in the inorganic light-emitting display panel may include a quantum dot, a quantum rod, and/or a micro LED. Hereinafter, it will be exemplified that the display panel DP is an organic light-emitting display panel.

The display panel DP may include a base layer BL, a drive element layer DP-CL, a light-emitting element layer DP-OLED, and a thin film encapsulation layer

TFE that are arranged on the base layer BL. The input sensor INS may be directly arranged on the thin film encapsulation layer TFE. The expression “component A is directly arranged on component B” utilized herein refers to that an adhesive layer is not arranged between component A and component B.

The base layer BL may include at least one plastic film. The base layer BL may be a flexible substrate and may include a plastic substrate, a glass substrate, a metal substrate, and/or an organic/inorganic composite substrate. The display area DA and the non-display area NDA described with reference to FIG. 1B may be identically defined at the base layer BL.

The drive element layer DP-CL may include at least one insulating layer and/or a circuit element. The insulating layer may include at least one inorganic layer and at least one organic layer. The circuit element may include signal lines and a pixel drive circuit.

The light-emitting element layer DP-OLED may include a barrier wall and a light-emitting element. The light-emitting element may include an anode, an intermediate layer, and a cathode.

The thin film encapsulation layer TFE may include a plurality of thin films. Some of the thin films may be arranged to improve optical efficiency, and the other thin films may be arranged to protect organic light-emitting diodes.

The input sensor INS obtains coordinate information of an external input. The input sensor INS may have a multi-layer structure. The input sensor INS may include a single conductive layer or multiple conductive layers. In addition, the input sensor INS may include a single insulating layer or multiple insulating layers. The input sensor INS may sense the external input in a capacitance type (kind). However, this is illustrative, and the present disclosure is not limited thereto. For example, in one or more embodiments, the input sensor INS may sense the external input utilizing an electromagnetic induction method or a pressure sensing method. In one or more embodiments, in one or more embodiments of the present disclosure, the input sensor INS may not be provided.

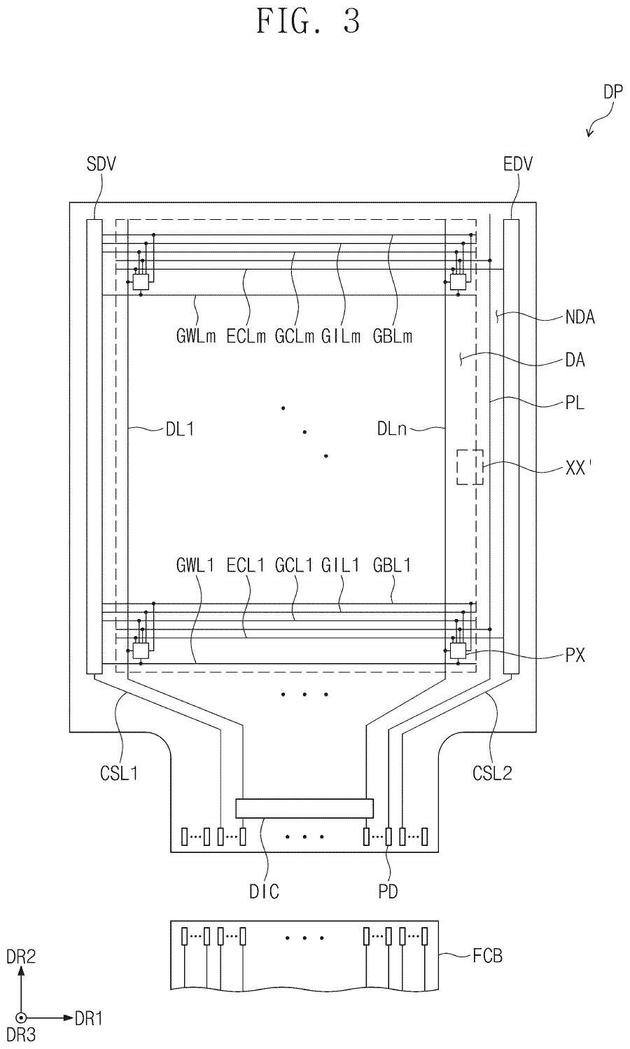

FIG. 3 is a plan view of the display panel DP according to one or more embodiments of the present disclosure.

Referring to FIG. 3, the display area DA and the non-display area NDA around the display area DA may be defined at the display panel DP. The display area DA and the non-display area NDA may be distinguished from each other depending on whether pixels PX are arranged. The pixels PX may be arranged at the display area DA. A scan driver SDV, a data driver, and an emission driver EDV may be arranged at the non-display area NDA. The data driver may be a circuit configured in the driver chip DIC.

The display panel DP may include the pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a drive voltage line PL, and a plurality of pads PD. Here, “m” and “n” are natural numbers of 2 or more.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1 and may be electrically connected to the scan driver SDV. The data lines DL1 to DLn may extend in the second direction DR2 and may be electrically connected to the driver chip DIC. The emission control lines ECL1 to ECLm may extend in the first direction DR1 and may be electrically connected to the emission driver EDV.

The drive voltage line PL may include a portion extending in the first direction DR1 and a portion extending in the second direction DR2. The portion extending in the first direction DR1 and the portion extending in the second direction DR2 may be arranged on different layers. The drive voltage line PL may provide a drive voltage to the pixels PX.

The first control line CSL1 may be connected to the scan driver SDV. The second control line CSL2 may be connected to the emission driver EDV.

The driver chip DIC, the drive voltage line PL, the first control line CSL1, and the second control line CSL2 may be electrically connected to the pads PD. A flexible circuit film FCB may be electrically connected to the pads PD through an anisotropic conductive adhesive layer.

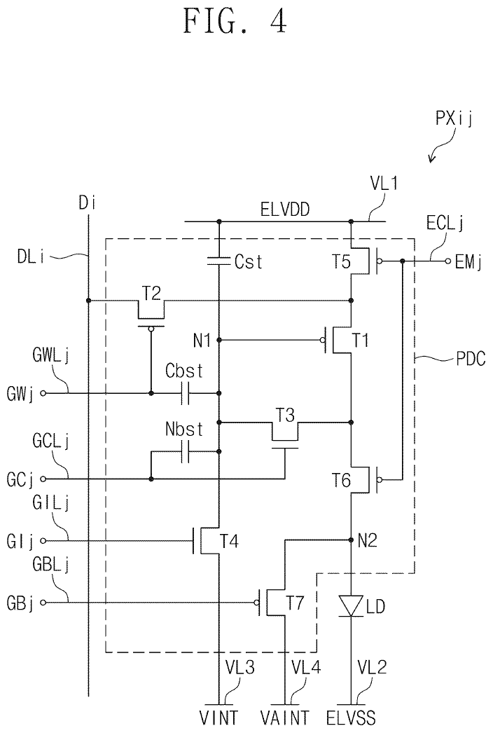

FIG. 4 is an equivalent circuit diagram of a pixel PXij according to one or more embodiments of the present disclosure.

In FIG. 4, an equivalent circuit diagram of one pixel PXij among the plurality of pixels PX (refer to FIG. 3) is illustrated as an example. Because the plurality of pixels PX have the same circuit structure, description of the circuit structure for the pixel PXij may be applied to the remaining pixels PX, and detailed description of the remaining pixels PX will not be provided.

Referring to FIGS. 3 and 4, the pixel PXij is connected to the i-th data line DLi among the data lines DL1 to DLn, the j-th initialization scan line GILj among the initialization scan lines GIL1 to GILm, the j-th compensation scan line GCLj among the compensation scan lines GCL1 to GCLm, the j-th write scan line GWLj among the write scan lines GWL1 to GWLm, the j-th black scan line GBLj among the black scan lines GBL1 to GBLm, the j-th emission control line ECLj among the emission control lines ECL1 to ECLm, first and second drive voltage lines VL1 and VL2, and first and second initialization voltage lines VL3 and VL4. Here, “i” is an integer of 1 to n, and “j” is an integer of 1 to m.

The pixel PXij includes a light-emitting element LD and a pixel driver PDC. The light-emitting element LD may be a light-emitting diode. In one or more embodiments of the present disclosure, the light-emitting element LD may be an organic light-emitting diode including an organic light-emitting layer, but is not particularly limited thereto. The pixel driver PDC may control the amount of current flowing through the light-emitting element LD in correspondence to an i-th data signal Di. The light-emitting element LD may be to emit light having a certain luminance in correspondence to the amount of current provided from the pixel driver PDC.

The pixel driver PDC may include first to seventh transistors T1, T2, T3, T4, T5, T6, and T7 and first to third capacitors Cst, Cbst, and Nbst. The configuration of the pixel driver PDC according to the present disclosure is not limited to one or more embodiments illustrated in FIG. 4. The pixel driver PDC illustrated in FIG. 4 is merely illustrative, and one or more suitable changes and modifications may be made to the configuration of the pixel driver PDC.

At least one of (e.g., selected from among) the first to seventh transistors T1, T2, T3, T4, T5, T6, and/or T7 may be a transistor having a low-temperature polycrystalline silicon (LTPS) semiconductor layer. At least one of the first to seventh transistors T1, T2, T3, T4, T5, T6, and/or T7 may be a transistor having an oxide semiconductor layer. For example, the third and fourth transistors T3 and T4 may be oxide semiconductor transistors, and the first, second, fifth, sixth, and seventh transistors T1, T2, T5, T6, and T7 may be LTPS transistors.

For example, the first transistor T1 directly affecting the brightness of the light-emitting element LD may include a semiconductor layer including (e.g., formed of) polycrystalline silicon having high reliability, and thus the display device having a high resolution may be implemented. In one or more embodiments, because an oxide semiconductor has high carrier mobility and low leakage current, a voltage drop is not great even though operating time is long. For example, the color of an image is not greatly changed depending on a voltage drop even during a low-frequency operation, and thus the low-frequency operation is possible. Because the oxide semiconductor has an advantage of low leakage current as described above, at least one of the third transistor T3, which is connected with a gate electrode of the first transistor T1, and the fourth transistor T4 may be employed as an oxide semiconductor to reduce power consumption while preventing or reducing leakage current that is likely to flow to the gate electrode.

Some of the first to seventh transistors T1, T2, T3, T4, T5, T6, and/or T7 may be P-type (kind) transistors, and the others may be N-type (kind) transistors. For example, the first, second, fifth, sixth, and seventh transistors T1, T2, T5, T6, and T7 may be P-type (kind) transistors, and the third and fourth transistors T3 and T4 may be N-type (kind) transistors.

The configuration of the pixel driver PDC according to the present disclosure is not limited to one or more embodiments illustrated in FIG. 4. The pixel driver PDC illustrated in FIG. 4 is merely illustrative, and one or more suitable changes and modifications may be made to the configuration of the pixel driver PDC. For example, the first to seventh transistors T1, T2, T3, T4, T5, T6, and T7 may all be P-type (kind) transistors or N-type (kind) transistors. In one or more embodiments, the first, second, fifth, and sixth transistors T1, T2, T5, and T6 may be P-type (kind) transistors, and the third, fourth, and seventh transistors T3, T4, and T7 may be N-type (kind) transistors.

The j-th initialization scan line GILj, the j-th compensation scan line GCLj, the j-th write scan line GWLj, the j-th black scan line GBLj, and the j-th emission control line ECLj may be to transmit the j-th initialization scan signal GIj, the j-th compensation scan signal GCj, the j-th write scan signal GWj, the j-th black scan signal GBj, and the j-th emission control signal EMj to the pixel PXij, respectively. The i-th data line DLi transfers the i-th data signal Di to the pixel PXij. The i-th data signal Di may have a voltage level corresponding to an image signal that is input to the display device DD (refer to FIG. 1).

The first drive voltage line VL1 and the second driver voltage line VL2 may transfer a first drive voltage ELVDD and a second drive voltage ELVSS to the pixel PXij, respectively. In addition, the first initialization voltage line VL3 and the second initialization voltage line VL4 may transfer a first initialization voltage VINT and a second initialization voltage VAINT to the pixel PXij, respectively. In this specification, the second drive voltage ELVSS may be referred to as a power supply voltage.

The first transistor T1 is connected between the first drive voltage line VL1, which receives the first drive voltage ELVDD, and the light-emitting element LD. The first transistor T1 includes a first electrode connected with the first drive voltage line VL1 via the fifth transistor T5, a second electrode connected with a pixel electrode (e.g., referred to as an anode) of the light-emitting element LD via the sixth transistor T6, and a third electrode (e.g., a gate electrode) connected with one end of the first capacitor Cst (e.g., a first node N1). The first transistor T1 may receive the i-th data signal Di that the i-th data line DLi transfers depending on a switching operation of the second transistor T2 and may supply a drive current to the light-emitting element LD.

The second transistor T2 is connected between the i-th data line DLi and the first electrode of the first transistor T1. The second transistor T2 includes a first electrode connected with the i-th data line DLi, a second electrode connected with the first electrode of the first transistor T1, and a third electrode (e.g., a gate electrode) connected with the j-th write scan line GWLj. The second transistor T2 may be turned on depending on the j-th write scan signal GWj transferred through the j-th write scan line GWLj and may transfer, to the first electrode of the first transistor T1, the i-th data signal Di transferred from the i-th data line DLi. One end of the second capacitor Cbst may be connected to the third electrode of the second transistor T2, and an opposite end of the second capacitor Cbst may be connected to the first node N1.

The third transistor T3 is connected between the second electrode of the first transistor T1 and the first node N1. The third transistor T3 includes a first electrode connected with the third electrode of the first transistor T1, a second electrode connected with the second electrode of the first transistor T1, and a third electrode (e.g., a gate electrode) connected with the j-th compensation scan line GCLj. The third transistor T3 may be turned on depending on the j-th compensation scan signal GCj transferred through the j-th compensation scan line GCLj and may diode-connect the first transistor T1 by connecting the third electrode of the first transistor T1 and the second electrode of the first transistor T1. One end of the third capacitor Nbst may be connected to the third electrode of the third transistor T3, and an opposite end of the third capacitor Nbst may be connected to the first node N1.

The fourth transistor T4 is connected between the first initialization voltage line VL3 through which the first initialization voltage VINT is applied and the first node N1. The fourth transistor T4 includes a first electrode connected with the first initialization voltage line VL3 through which the first initialization voltage VINT is transferred, a second electrode connected with the first node N1, and a third electrode (e.g., a gate electrode) connected with the j-th initialization scan line GILj. The fourth transistor T4 is turned on depending on the j-th initialization scan signal Glj transferred through the j-th initialization scan line GILj. The turned-on fourth transistor T4 initializes the potential of the third electrode of the first transistor T1 (e.g., the potential of the first node N1) by transferring the first initialization voltage VINT to the first node N1.

The fifth transistor T5 includes a first electrode connected with the first drive voltage line VL1, a second electrode connected with the first electrode of the first transistor T1, and a third electrode (e.g., a gate electrode) connected to the j-th emission control line ECLj. The sixth transistor T6 includes a first electrode connected with the second electrode of the first transistor T1, a second electrode connected to the pixel electrode of the light-emitting element LD, and a third electrode (e.g., a gate electrode) connected to the j-th emission control line ECLj.

The fifth transistor T5 and the sixth transistor T6 are concurrently (e.g., simultaneously) turned on depending on the j-th emission control signal EMj transferred through the j-th emission control line ECLj. The first drive voltage ELVDD applied through the turned-on fifth transistor T5 may be compensated for through the diode-connected first transistor T1 and thereafter may be transferred to the light-emitting element LD through the sixth transistor T6.

The seventh transistor T7 includes a first electrode connected to the second initialization voltage line VL4 through which the second initialization voltage VAINT is transferred, a second electrode connected with the second electrode of the sixth transistor T6 (or a second node N2), and a third electrode (e.g., a gate electrode) connected with the j-th black scan line GBLj. The second initialization voltage VAINT may have a voltage level lower than or equal to the voltage level of the first initialization voltage VINT.

The one end of the first capacitor Cst is connected with the third electrode of the first transistor T1, and the opposite end of the first capacitor Cst is connected with the first drive voltage line VL1. A cathode of the light-emitting element LD may be connected with the second drive voltage line VL2 that transfers the second drive voltage ELVSS. The second drive voltage ELVSS may have a lower voltage level than the first drive voltage ELVDD.

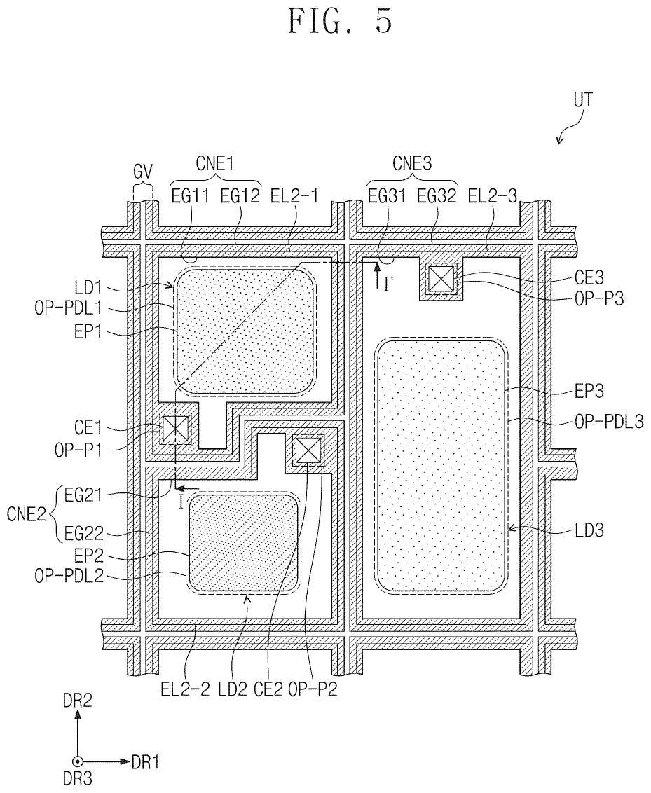

FIG. 5 is an enlarged plan view of a partial area of the display panel according to one or more embodiments of the present disclosure. Among components of the display panel, a groove GV, and a plurality of second electrodes (e.g., cathodes) EL2-1, EL2-2, and EL2-3, a plurality of light-emitting parts EP1, EP2, and EP3, and a plurality of connecting electrodes CNE1, CNE2, and CNE3 arranged at areas divided from one another by the groove GV are illustrated in FIG. 5. For ease of description, one light-emitting unit UT including the light-emitting parts EP1, EP2, and EP3 is illustrated as an example.

Referring to FIG. 5, light-emitting elements LD1, LD2, and LD3 may include

the first light-emitting element LD1, the second light-emitting element LD2, and the third light-emitting element LD3. The first light-emitting element LD1 may include a first anode, a first intermediate layer, and the first cathode EL2-1. The second light-emitting element LD2 may include a second anode, a second intermediate layer, and the second cathode EL2-2. The third light-emitting element LD3 may include a third anode, a third intermediate layer, and the third cathode EL2-3.

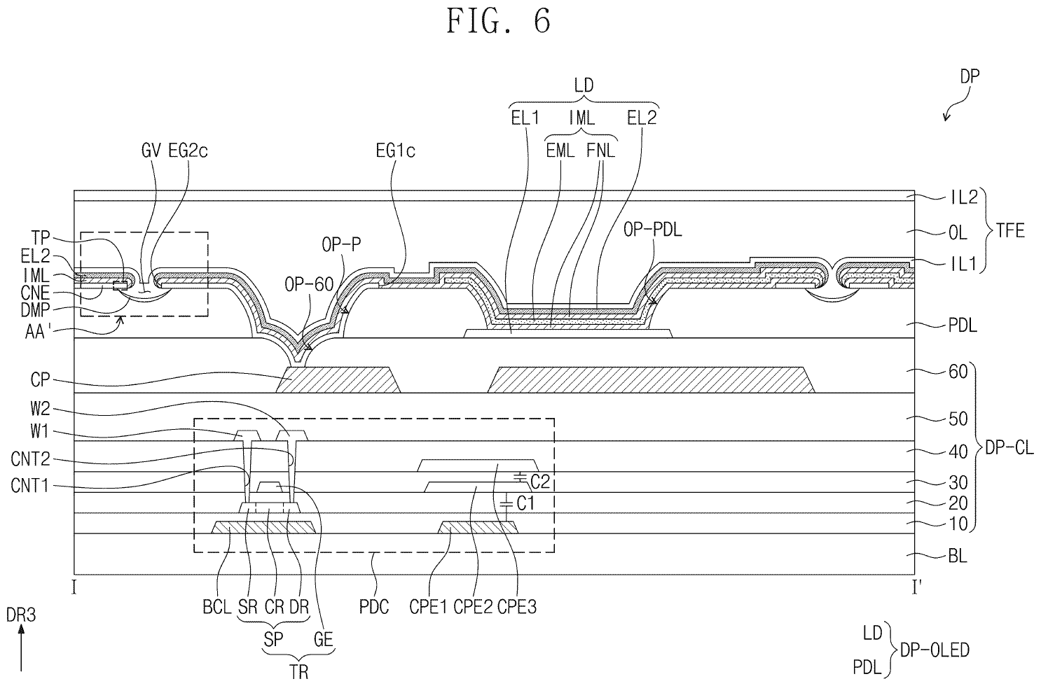

Each of the light-emitting parts EP1, EP2, and EP3 may correspond to a light-emitting opening OP-PDL (refer to FIG. 6) that will be described in more detail. For example, the light-emitting parts EP1, EP2, and EP3 may be areas through which light is emitted by the above-described light-emitting elements. The light-emitting parts EP1, EP2, and EP3 may correspond to a unit (e.g., the light-emitting unit UT) that forms an image displayed on the display panel DP (refer to FIG. 2). For example, each of the light-emitting parts EP1, EP2, and EP3 may correspond to an area defined by the light-emitting opening OP-PDL that will be described in more detail, for example, an area defined by the lower surface of the light-emitting opening OP-PDL.

The light-emitting parts EP1, EP2, and EP3 may include the first light-emitting part EP1, the second light-emitting part EP2, and the third light-emitting part EP3. The first light-emitting part EP1, the second light-emitting part EP2, and the third light-emitting part EP3 may be to emit light of different colors. For example, the first light-emitting part EP1 may be to emit red light, the second light-emitting part EP2 may be to emit green light, and the third light-emitting part EP3 may be to emit blue light. However, a combination of colors is not limited thereto. In one or more embodiments, at least two of the first to third light-emitting parts EP1, EP2, and EP3 may be to emit light of the same color. For example, the first to third light-emitting parts EP1, EP2, and EP3 may be all to emit blue light or white light.

In FIG. 5, the third light-emitting part EP3 is illustrated as being provided as one pattern having a one-body shape, but the present disclosure is not limited thereto. For example, the third light-emitting part EP3 may include two sub-light-emitting parts spaced and/or apart (e.g., spaced apart or separated) from each other.

The second electrodes EL2-1, EL2-2, and EL2-3 (hereinafter, referred to as the first to third cathodes) may be separated and electrically disconnected from one another by the groove GV. For example, the first cathode EL2-1 may be separated and electrically disconnected from the second cathode EL2-2, the second cathode EL2-2 may be separated and electrically disconnected from the third cathode EL2-3, and the third cathode EL2-3 may be separated and electrically disconnected from the first cathode EL2-1. In this embodiment, one light-emitting unit UT may include three light-emitting parts EP1, EP2, and EP3. Accordingly, the light-emitting unit UT may include three cathodes EL2-1, EL2-2, and EL2-3, three pixel drivers PDC (refer to FIG. 4), and three connecting electrodes CNE1, CNE2, and CNE3. However, this is illustrative, and the number and arrangement of light-emitting parts included in the light-emitting unit UT may be designed in one or more suitable ways and are not limited thereto.

The plurality of pixel drivers PDC are electrically connected to the first to third light-emitting elements LD1, LD2, and LD3 including the first to third light-emitting parts EP1, EP2, and EP3, respectively. The plurality of pixel drivers PDC may include a first pixel driver connected with the first light-emitting element LD1, a second pixel driver connected with the second light-emitting element LD2, and a third pixel driver connected with the third light-emitting element LD3. The expression “connected” utilized herein includes not only a physical direct contact but also an electrical connection.

The positions of the plurality of pixel drivers PDC may be independently designed irrespective of the positions or shapes of the first to third light-emitting parts EP1, EP2, and EP3. For example, the first to third pixel drivers PDC may be arranged at positions different from the areas divided from one another by the groove GV (e.g., the positions at which the first to third cathodes EL2-1, EL2-2, and EL2-3 are arranged) or may be designed to have shapes and areas different from the shapes of the first to third cathodes EL2-1, EL2-2, and EL2-3. In one or more embodiments, the plurality of pixel drivers PDC may be arranged to overlap the positions where the first to third light-emitting parts EP1, EP2, and EP3 exist and may be designed in shapes similar to the shapes of the areas divided from one another by the groove GV, for example, the first to third cathodes EL2-1, EL2-2, and EL2-3.

The light-emitting unit UT may include the first to third connecting electrodes CNE1, CNE2, and CNE3. The first connecting electrode CNE1 may electrically connect the first light-emitting element LD1 that forms the first light-emitting part EP1 (e.g., has the first light-emitting part EP1 defined therein) and the first pixel driver, the second connecting electrode CNE2 may electrically connect the second light-emitting element LD2 that forms the second light-emitting part EP2 and the second pixel driver, and the third connecting electrode CNE3 may electrically connect the third light-emitting element LD3 that forms the third light-emitting part EP3 and the third pixel driver.

For example, the first to third connecting electrodes CNE1, CNE2, and CNE3 may electrically connect the first to third cathodes EL2-1, EL2-2, and EL2-3 and the first to third pixel drivers in a one-to-one correspondence.

Each of the first to third connecting electrodes CNE1, CNE2, and CNE3 may be arranged on a pixel defining layer PDL (refer to FIG. 6) that will be described in more detail. The first to third connecting electrodes CNE1, CNE2, and CNE3 may have ring shapes that be around (e.g., surround) the corresponding first to third light-emitting parts EP1, EP2, and EP3. In one or more embodiments of the present disclosure, each of the first to third connecting electrodes CNE1, CNE2, and CNE3 is illustrated as having a closed-line ring shape, but the present disclosure is not limited thereto. For example, at least some of (e.g., selected from among) the first to third connecting electrodes CNE1, CNE2, and/or CNE3 may have an open ring shape in which a portion is cut off.

Because the first to third connecting electrodes CNE1, CNE2, and CNE3 have a ring shape, the degree of freedom of the positions at which the first to third connecting electrodes CNE1, CNE2, and CNE3 and the first to third pixel drivers are connected may be improved. For example, the first connecting electrode CNE1 may be connected to the first pixel driver through a first connection part CE1, the second connecting electrode CNE2 may be connected to the second pixel driver through a second connection part CE2, and the third connecting electrode CNE3 may be connected to the third pixel driver through a third connecting part CE3. For example, connecting lines additionally connected to the first connecting electrode CNE1 and the second connecting electrode CNE2 may not be provided.

The first connecting electrode CNE1 may include a first edge EG11 around (e.g., surrounding) at least a portion of the first light-emitting part EP1 and a second edge EG12 around (e.g., surrounding) the first edge EG11. The second connecting electrode CNE2 may include a first edge EG21 around (e.g., surrounding) at least a portion of the second light-emitting part EP2 and a second edge EG22 around (e.g., surrounding) the first edge EG21. The third connecting electrode CNE3 may include a first edge EG31 around (e.g., surrounding) at least a portion of the third light-emitting part EP3 and a second edge EG32 around (e.g., surrounding) the first edge EG31.

The gap between connecting electrodes adjacent to each other among the first to third connecting electrodes CNE1, CNE2, and CNE3 (e.g., the plurality of connecting electrodes) may overlap the groove GV. For example, the groove GV may overlap the gap between two adjacent connecting electrodes arranged on the pixel defining layer PDL.

In one or more embodiments of the present disclosure, the first to third connection parts CE1, CE2, and CE3 may be arranged at positions not overlapping the first to third light-emitting parts EP1, EP2, and EP3 if (e.g., when) viewed from above the plane. For example, the light-emitting opening OP-PDL (refer to FIG. 6) and through-holes OP-P (refer to FIG. 6) spaced and/or apart (e.g., spaced apart or separated) from the light-emitting opening OP-PDL may be defined at (e.g., in) the pixel defining layer PDL.

The through-holes OP-P may include a first through-hole OP-P1, a second through-hole OP-P2, and a third through-hole OP-P3. The first to third connection parts CE1, CE2, and CE3 may be arranged to correspond to the first to third through-holes OP-P1, OP-P2, and OP-P3, respectively. The light-emitting opening OP-PDL may include a first light-emitting opening OP-PDL1, a second light-emitting opening OP-PDL2, and a third light-emitting opening OP-PDL3. The first to third light-emitting parts EP1, EP2, and EP3 may be defined to correspond to the first to third light-emitting openings OP-PDL1, OP-PDL2, and OP-PDL3, respectively. Accordingly, the first to third connection parts CE1, CE2, and CE3 may be arranged at positions spaced and/or apart (e.g., spaced apart or separated) from the first to third light-emitting parts EP1, EP2, and EP3.

If (e.g., when) viewed from above the plane, the first connecting electrode CNE1 may be around (e.g., surround) the first light-emitting opening OP-PDL1, the second connecting electrode CNE2 may be around (e.g., surround) the second light-emitting opening OP-PDL2, and the third connecting electrode CNE3 may be around (e.g., surround) the third light-emitting opening OP-PDL3.

The first to third cathodes EL2-1, EL2-2, and EL2-3 may be connected with the first to third connecting electrodes CNE1, CNE2, and CNE3. For example, the first to third cathodes EL2-1, EL2-2, and EL2-3 may be connected with (e.g., brought into contact with) the first to third connecting electrodes CNE1, CNE2, and CNE3 in areas adjacent to the groove GV. The first to third cathodes EL2-1, EL2-2, and EL2-3 may be connected to a conductive pattern CP (refer to FIG. 6) through the first to third connecting electrodes CNE1, CNE2, and CNE3, and the conductive pattern CP may electrically connect the power supply voltage (e.g., the second drive voltage) ELVSS (refer to FIG. 4) and the first to third cathodes EL2-1, EL2-2, and EL2-3.

In addition, connection areas where the first to third cathodes EL2-1, EL2-2, and EL2-3 and the first to third connecting electrodes CNE1, CNE2, and CNE3 are connected may be around (e.g., surround) at least portions of the first to third light-emitting openings OP-PDL1, OP-PDL2, and OP-PDL3. The first to third cathodes EL2-1, EL2-2, and EL2-3 and the first to third connecting electrodes CNE1, CNE2, and CNE3 may be connected at the areas adjacent to the groove GV, and the connection areas may be defined to be adjacent to the groove GV. For example, the first to third cathodes EL2-1, EL2-2, and EL2-3 and the first to third connecting electrodes CNE1, CNE2, and CNE3 may not be connected at specific points and may be connected over relatively wide areas, for example, areas similar to the shapes of the first to third connecting electrodes CNE1, CNE2, and CNE3. For example, the areas of the connection areas may be increased, and thus the connection may be stably performed.

FIG. 6 is a sectional view of the display panel DP according to one or more embodiments of the present disclosure. FIG. 6 illustrates a sectional view illustrating a portion corresponding to line I-I′ of FIG. 5.

Referring to FIG. 6, the display panel DP of one or more embodiments may include the base layer BL, the drive element layer DP-CL, the light-emitting element layer DP-OLED, and the thin film encapsulation layer TFE.

The base layer BL may be a member that provides a base surface on which a pixel driver PDC is arranged. The base layer BL may be a rigid substrate or may be a flexible substrate capable of being bent, folded, and/or rolled. The base layer BL may be a glass substrate, a metal substrate, and/or a polymer substrate. However, one or more embodiments of the present disclosure are not limited thereto, and the base layer BL may be an inorganic layer, an organic layer, and/or a composite layer.

The base layer BL may have a multi-layer structure. The base layer BL may include a first polymer resin layer, a silicon oxide (e.g., SiOₓ, 0<x≤2) layer arranged on the first polymer resin layer, an amorphous silicon (a-Si) layer arranged on the silicon oxide layer, and a second polymer resin layer arranged on the amorphous silicon layer. The silicon oxide layer and the amorphous silicon layer may be referred to as a base barrier layer.

The polymer resin layers may include a polyimide-based resin. In one or more embodiments, the polymer resin layers may include at least one of an acrylic resin, a methacrylic resin, a polyisoprene resin, a vinyl resin, an epoxy resin, a urethane-based resin, a celluosic resin, a siloxane-based resin, a polyamide resin, and/or a perylene-based resin. In one or more embodiments, a “˜˜”-based resin utilized herein refers to a resin containing a “˜˜” functional group.

Each of insulating layers, conductive layers, and semiconductor layers arranged on the base layer BL may be formed by a method such as coating and/or deposition. Thereafter, the insulating layers, the semiconductor layers, and the conductive layers may be selectively subjected to patterning by performing a photolithography process a plurality of times. Accordingly, holes may be formed at the insulating layers, or a semiconductor pattern, a conductive pattern, and a signal line may be formed on the insulating layers.

The drive element layer DP-CL may include a plurality of insulating layers 10, 20, 30, 40, 50, and 60 arranged on the base layer BL and a plurality of conductive patterns and semiconductor patterns arranged between the insulating layers 10, 20, 30, 40, 50, and 60. The conductive patterns and the semiconductor patterns may be arranged between the insulating layers 10, 20, 30, 40, 50, and 60 to constitute the pixel driver PDC. In FIG. 6, for ease of description, a cross-section of a partial region of an area in which one light-emitting part is arranged is illustrated.

The first insulating layer 10 may be arranged on the base layer BL. The first insulating layer 10 may be an inorganic layer and/or an organic layer and may have a single-layer structure or a multi-layer structure. The first insulating layer 10 may include at least one of aluminum oxide, titanium oxide, silicon oxide, silicon nitride, silicon oxy nitride, zirconium oxide, and/or hafnium oxide. In this embodiment, the first insulating layer 10 is illustrated as a single silicon oxide layer. In one or more embodiments, insulating layers to be described in more detail may be inorganic layers and/or organic layers and may have a single-layer structure or a multi-layer structure. The inorganic layers may include at least one of the aforementioned materials, but are not limited thereto.

In one or more embodiments, the first insulating layer 10 may cover a lower conductive layer BCL. For example, the display panel DP may further include the lower conductive layer BCL arranged to overlap a transistor TR. The lower conductive layer BCL may block or reduce an influence of an electric potential due to a polarization phenomenon between the base layer BL and the transistor TR (e.g., the base layer BL located on (e.g., below) the transistor TR). For example, the base layer BL and the transistor TR may render a polarization effect in operation which causes an electric potential (e.g., energy transferred in the third direction DR3 under a static electric field), and the lower conductive layer BCL may block the impact caused by such electric potential. In addition, the lower conductive layer BCL may block or reduce light incident to the transistor TR from below (e.g., light coming in along the third direction DR3). For example, the lower conductive layer BCL may block the light coming from the direction where the base layer BL is. At least one of an inorganic barrier layer and a buffer layer may be additionally arranged between the lower conductive layer BCL and the base layer BL.

The lower conductive layer BCL may include reflective metal. For example, the lower conductive layer BCL may include titanium (Ti), molybdenum (Mo), an alloy containing molybdenum and aluminum (AI), and/or an alloy containing aluminum, aluminum nitride (AlN), tungsten (W), tungsten nitride (WN), and/or copper (Cu).

In one or more embodiments, the lower conductive layer BCL may be connected with a source of the transistor TR through a source electrode pattern W1. In this case, the lower conductive layer BCL may be synchronized with the source of the transistor TR. However, this is illustrative, and the lower conductive layer BCL may be connected to a gate of the transistor TR and may be synchronized with the gate. In one or more embodiments, the lower conductive layer BCL may be connected to another electrode and may independently receive a constant voltage or a pulse signal. In another case, the lower conductive layer BCL may be provided in a form isolated from another conductive pattern. In one or more embodiments, the lower conductive layer BCL may be provided in one or more suitable forms and is not limited thereto.

The transistor TR may be arranged on the first insulating layer 10. The transistor TR may include a semiconductor pattern SP and a gate electrode GE. The semiconductor pattern SP may be on (e.g., disposed on) the first insulating layer 10. The semiconductor pattern SP may include an oxide semiconductor. For example, the oxide semiconductor may include transparent conductive oxide (TCO) such as indium tin oxide (e.g., ITO), indium zinc oxide (e.g., IZO), indium gallium zinc oxide (e.g., IGZO), zinc oxide (e.g., ZnO), and/or indium oxide (e.g., In₂O₃). However, without being limited thereto, the semiconductor pattern SP may include amorphous silicon, low-temperature polycrystalline silicon, and/or polycrystalline silicon.

The semiconductor pattern SP may include a source area SR, a drain area DR, and a channel area CR distinguished from one another depending on the degree of conductivity. The channel area CR may be a portion overlapping the gate electrode GE if (e.g., when) viewed from above the plane. The source area SR and the drain area DR may be portions spaced and/or apart (e.g., spaced apart or separated) from each other with the channel area CR therebetween. If (e.g., when) the semiconductor pattern SP is an oxide semiconductor, the source area SR and the drain area DR may be reduced areas. Accordingly, the source area SR and the drain area DR may have a higher reduced-metal content (e.g., amount) than the channel area CR. In one or more embodiments, if (e.g., when) the semiconductor pattern SP is polycrystalline silicon, the source area SR and the drain area DR may be highly doped areas.

The source area SR and the drain area DR may have a higher conductivity than the channel area CR. The source area SR may correspond to the source electrode of the transistor TR, and the drain area DR may correspond to the drain electrode of the transistor TR. As illustrated in FIG. 6, the drive element layer DP-CL may further include the source electrode pattern W1 and a drain electrode pattern W2 connected to the source area SR and the drain area DR, respectively.

The second insulating layer 20 may commonly overlap a plurality of pixels and may cover the semiconductor pattern SP. The second insulating layer 20 may be an inorganic layer and/or an organic layer and may have a single-layer structure or a multi-layer structure. The second insulating layer 20 may include at least one of aluminum oxide, titanium oxide, silicon oxide, silicon nitride, silicon oxy nitride, zirconium oxide, and/or hafnium oxide. For example, the second insulating layer 20 may be a single silicon oxide layer.

The gate electrode GE may be arranged on the second insulating layer 20. The gate electrode GE may correspond to the gate of the transistor TR. In addition, the gate electrode GE may be arranged over the semiconductor pattern SP. However, this is illustrative, and the gate electrode GE may be arranged under the semiconductor pattern SP and is not limited thereto.

The gate electrode GE may include titanium (Ti), silver (Ag), molybdenum (Mo), aluminum (AI), aluminum nitride (e.g., AlN), tungsten (W), tungsten nitride (e.g., WN), copper (Cu), and/or an alloy thereof, but is not particularly limited thereto.

The third insulating layer 30 may be arranged on the gate electrode GE. The third insulating layer 30 may be an inorganic layer and/or an organic layer and may have a single-layer structure or a multi-layer structure.

Among a plurality of conductive patterns, the first capacitor electrode CPE1 and the second capacitor electrode CPE2 constitute a first capacitor C1. The first capacitor electrode CPE1 and the second capacitor electrode CPE2 may be spaced and/or apart (e.g., spaced apart or separated) from each other with the first insulating layer 10 and the second insulating layer 20 therebetween. In one or more embodiments of the present disclosure, the first capacitor electrode CPE1 and the lower conductive layer BCL may have a one-body shape. In addition, the second capacitor electrode CPE2 and the gate electrode GE may have a one-body shape.

The third capacitor electrode CPE3 may be arranged on the third insulating layer 30. The third capacitor electrode CPE3 may be spaced and/or apart (e.g., spaced apart or separated) from the second capacitor electrode CPE2 with the third insulating layer 30 therebetween and may overlap the second capacitor electrode CPE2 if (e.g., when) viewed from above the plane. The third capacitor electrode CPE3, together with the second capacitor electrode CPE2, may constitute a second capacitor C2.

The fourth insulating layer 40 may be arranged on the third insulating layer 30 and/or the third capacitor electrode CPE3. The fourth insulating layer 40 may be an inorganic layer and/or an organic layer and may have a single-layer structure or a multi-layer structure. The fourth insulating layer 40 may include at least one of aluminum oxide, titanium oxide, silicon oxide, silicon nitride, silicon oxynitride, zirconium oxide, and/or hafnium oxide.

The source electrode pattern W1 and the drain electrode pattern W2 may be arranged on the fourth insulating layer 40. The source electrode pattern W1 may be connected to the source area SR of the transistor TR through a first contact hole CNT1, and the source electrode pattern W1 and the source area SR of the semiconductor pattern SP may function as the source of the transistor TR. The drain electrode pattern W2 may be connected to the drain area DR of the transistor TR through a second contact hole CNT2, and the drain electrode pattern W2 and the drain area DR of the semiconductor pattern SP may function as the drain area DR of the transistor TR.

The fifth insulating layer 50 may be arranged on the source electrode pattern W1 and the drain electrode pattern W2. The conductive pattern CP may be arranged at (e.g., in) the drive element layer DP-CL. For example, the conductive pattern CP may be arranged on the fifth insulating layer 50. The conductive pattern CP may be electrically connected with the power supply voltage (e.g., the second drive voltage) ELVSS (refer to FIG. 4).

The sixth insulating layer 60 may be arranged on the fifth insulating layer 50. The sixth insulating layer 60 may be arranged on the fifth insulating layer 50 and may cover at least a portion of the conductive pattern CP. Each of the fifth insulating layer 50 and the sixth insulating layer 60 may be an organic layer. For example, each of the fifth insulating layer 50 and the sixth insulating layer 60 may include a general purpose polymer, such as benzocyclobutene (BCB), polyimide, hexamethyldisiloxane (HMDSO), Polymethylmethacrylate (PMMA), and/or Polystyrene (PS), a polymer derivative having a phenolic group, an acrylic-based polymer, an imide-based polymer, an aryl ether-based polymer, an amide-based polymer, a fluorine-based polymer, a p-xylene-based polymer, a vynyl alcohol-based polymer, and/or a blend thereof.

A through-hole OP-60 that exposes at least a portion of the conductive pattern CP may be formed at the sixth insulating layer 60. The conductive pattern CP may be connected to a connecting electrode CNE through a portion exposed from the sixth insulating layer 60 and may be electrically connected with a light-emitting element LD.

The light-emitting element layer DP-OLED may be arranged on the drive element layer DP-CL. The light-emitting element layer DP-OLED may include the pixel defining layer PDL and the light-emitting element LD.

The pixel defining layer PDL may be an organic layer. For example, the pixel defining layer PDL may include a general purpose polymer, such as benzocyclobutene (BCB), polyimide, hexamethyldisiloxane (HMDSO), Polymethylmethacrylate (PMMA), and/or Polystyrene (PS), a polymer derivative having a phenolic group, an acrylic-based polymer, an imide-based polymer, an aryl ether-based polymer, an amide-based polymer, a fluorine-based polymer, a p-xylene-based polymer, a vynyl alcohol-based polymer, and/or a blend thereof.

In one or more embodiments, the pixel defining layer PDL may have a property of absorbing light. For example, the pixel defining layer PDL may be black in color. For example, the pixel defining layer PDL may include a black coloring agent. The black coloring agent may include a black dye and/or a black pigment. The black coloring agent may include carbon black, and/or metal such as chromium, and/or oxide thereof. The pixel defining layer PDL may correspond to a light blocking pattern having light-blocking characteristics.

The opening OP-PDL (hereinafter, referred to as the light-emitting opening) that exposes at least a portion of a first electrode EL1 that will be described in more detail may be defined at (e.g., in) the pixel defining layer PDL. A plurality of light-emitting openings OP-PDL may be provided. The plurality of light-emitting openings OP-PDL may be arranged to correspond to light-emitting elements LD, respectively. All components of the light-emitting element LD may be arranged at the light-emitting opening OP-PDL to overlap one another, and the light-emitting opening OP-PDL may be an area where light emitted by the light-emitting element LD is substantially displayed. Accordingly, the shape of the first light-emitting part EP1 (refer to FIG. 5) may substantially correspond to the shape of the light-emitting opening OP-PDL if (e.g., when) viewed from above the plane.

The connecting electrode CNE may be arranged on the pixel defining layer PDL. The connecting electrode CNE may electrically connect the conductive pattern CP and a second electrode EL2 of the light-emitting element LD. The connecting electrode CNE may correspond to the first connecting electrode CNE1 illustrated in FIG. 5. The second connecting electrode CNE2 (refer to FIG. 5) and the third connecting electrode CNE3 (refer to FIG. 5) may also have a structure similar to that of the connecting electrode CNE.

The connecting electrode CNE may include a first edge EG1c adjacent to the light-emitting opening OP-PDL and a second edge EG2c around (e.g., surrounding) the first edge EG1c. The second electrode EL2 of the light-emitting element LD may be brought into contact with the connecting electrode CNE in an area adjacent to the second edge EG2c. For example, the second electrode EL2 and the connecting electrode CNE may be connected with (e.g., brought into contact with) each other in an area adjacent to a groove GV that will be described in more detail.

The connecting electrode CNE may include transparent conductive oxide (TCO) such as indium tin oxide (e.g., ITO), indium zinc oxide (e.g., IZO), indium gallium zinc oxide (e.g., IGZO), zinc oxide (e.g., ZnO), and/or indium oxide (e.g., In₂O₃). However, the material constituting the connecting electrode CNE is not limited thereto.

The pixel defining layer PDL may be arranged on the drive element layer DP-CL. The light-emitting opening OP-PDL that exposes at least a portion of the first electrode EL1 and the groove GV around (e.g., surrounding) the light-emitting opening OP-PDL may be defined at (e.g., in) the pixel defining layer PDL. The groove GV may be formed by removing a portion of the pixel defining layer PDL in the thickness direction of the pixel defining layer PDL (e.g., the third direction DR3).

A portion of the connecting electrode CNE may protrude from the end of the groove GV toward the center of the groove GV. The portion of the connecting electrode CNE may be defined as a tip portion TP. For example, the connecting electrode CNE may include the tip portion TP. Because the tip portion TP protrudes toward the groove GV, the connecting electrode CNE may partially overlap the groove GV if (e.g., when) viewed from above the plane. The second electrode EL2 of the light-emitting element LD and the connecting electrode CNE may be connected with (e.g., brought into contact with) each other at the tip portion TP.

In one or more embodiments, the second electrode EL2 and a functional layer FNL may be commonly formed for the plurality of pixels by deposition through an open mask. A portion of the functional layer FNL may include an organic layer. If (e.g., when) the organic layer is commonly formed, lateral leakage current may occur due to the organic layer provided in common between adjacent pixels, which may cause color mixing between the adjacent pixels and a defect in luminance. In one or more embodiments, in this specification, the “lateral leakage current” refers to a current flowing in another direction crossing the third direction DR3 other than a current flowing in the third direction DR3, which is the stacking direction of the light-emitting element LD, e.g., in the direction in which an image is displayed. The lateral leakage current may refer to a current flowing in a direction parallel to a plane defined by the first direction DR1 and the second direction DR2.

According to the present disclosure, to prevent or reduce the occurrence of lateral leakage current between adjacent pixels, an intermediate layer IML and the second electrode EL2 may be separated for each pixel by the tip portion TP of the connecting electrode CNE. Accordingly, the occurrence of lateral leakage current may be prevented or reduced, and thus color mixing between adjacent pixel areas and deterioration in luminance may be prevented or reduced. The tip portion TP of the connecting electrode CNE may have a closed-line shape for each of the light-emitting parts, and thus the second electrode EL2 and the functional layer FNL may have a split shape for each light-emitting part. For example, the second electrode EL2 and the intermediate layer IML may be electrically independent for each of adjacent pixels.

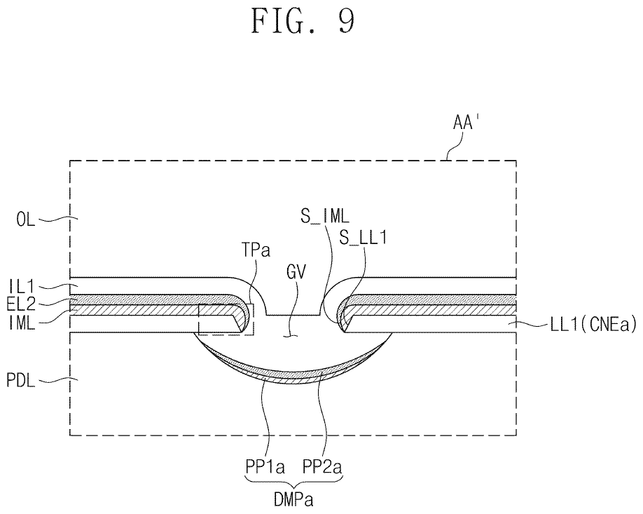

The tip portion TP may have an inverted tapered shape. For example, the taper angle formed by the lower surface of the connecting electrode CNE and the side surface of the connecting electrode CNE may be an obtuse angle. However, this is illustrative, and the taper angle may be set in one or more suitable ways as long as the tip portion TP of the connecting electrode CNE is capable of electrically disconnecting the second electrode EL2 for each pixel. For example, if (e.g., when) a connecting electrode CNEa (refer to FIG. 9) includes only a first connecting electrode layer LL1 (refer to FIG. 9), the taper angle formed by the lower surface of the connecting electrode CNEa and the side surface of the connecting electrode CNEa may be an acute angle or a right angle.

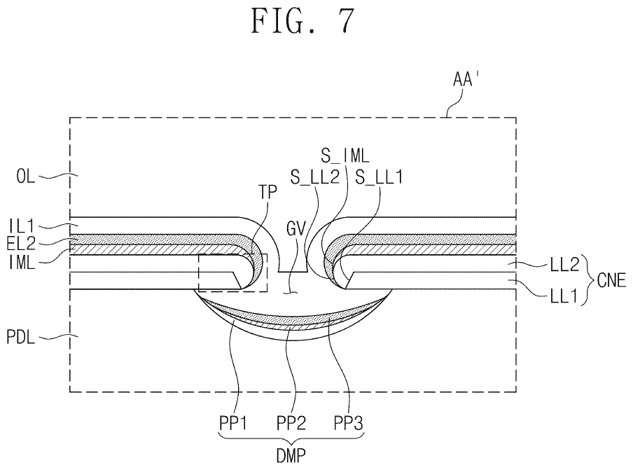

Dummy patterns DMP may be arranged at (e.g., in) the groove GV. The dummy patterns DMP may be formed by separating a portion of the connecting electrode CNE (e.g., a second connecting electrode layer LL2 (refer to FIG. 7)), the second electrode EL2, or the functional layer FNL by the tip portion TP of the connecting electrode CNE. However, this is illustrative, and the present disclosure is not limited thereto. Detailed description will be given with reference to FIGS. 7 to 11.

The through-hole OP-P spaced and/or apart (e.g., spaced apart or separated) from the light-emitting opening OP-PDL may be defined at (e.g., in) the pixel defining layer PDL. A plurality of through-holes OP-P may be provided. The plurality of through-holes OP-P may be arranged to correspond to the light-emitting elements LD, respectively. The size of the through-hole OP-P defined at (e.g., in) the pixel defining layer PDL may be greater than the size of the through-hole OP-60 defined at the sixth insulating layer 60. The connecting electrode CNE may be arranged at the through-hole OP-P and the through-hole OP-60. For example, the connecting electrode CNE may be connected with the pixel driver PDC through the through-hole OP-P and the through-hole OP-60.

The light-emitting element LD may include the first electrode EL1, the intermediate layer IML, and the second electrode EL2. The intermediate layer IML may be an emission pattern.

The first electrode EL1 may be a transflective electrode, a transmissive electrode, or a reflective electrode. According to one or more embodiments of the present disclosure, the first electrode EL1 may include a reflective layer including (e.g., formed of) silver (Ag), magnesium (Mg), aluminum (Al), platinum (Pt), palladium (Pd), gold (Au), nickel (Ni), neodymium (Nd), iridium (Ir), chromium (Cr), and/or a compound thereof and a transparent or translucent electrode layer formed on the reflective layer. The transparent or translucent electrode layer may include at least one selected from among the group consisting of indium tin oxide (e.g., ITO), indium zinc oxide (e.g., IZO), indium gallium zinc oxide (e.g., IGZO), zinc oxide (e.g., ZnO), and/or indium oxide (e.g., In₂O₃) and aluminum-doped zinc oxide (e.g., AZO). For example, the first electrode EL1 may include a stacked structure of ITO/Ag/ITO (e.g., a stacked structure including a layer of ITO, a layer of Ag, and a layer of ITO).

In this embodiment, the first electrode EL1 may be an anode of the light-emitting element LD. For example, the first electrode EL1 may be connected with the first drive voltage line VL1 (refer to FIG. 4) and may receive the first drive voltage ELVDD (refer to FIG. 4). The first electrode EL1 may be connected with the first drive voltage line VL1 at the display area DA (refer to FIG. 3) or may be connected with the first drive voltage line VL1 at the non-display area NDA. In the latter case, the first drive voltage line VL1 may be arranged at the non-display area NDA (refer to FIG. 3), and the first electrode EL1 may have a shape extending to the non-display area NDA.

In the sectional view of FIG. 6, the first electrode EL1 is illustrated as overlapping the light-emitting opening OP-PDL and not overlapping the groove GV. However, the first electrodes EL1 of the light-emitting elements LD may have a one-body shape and may have a mesh or grid shape in which openings are defined at a partial area. For example, as long as the same first drive voltage ELVDD is capable of being applied to the first electrodes EL1 of the plurality of light-emitting elements LD, the shape of the first electrode EL1 may be provided in one or more suitable ways and is not limited thereto.

The intermediate layer IML may be arranged between the first electrode EL1 and the second electrode EL2. The intermediate layer IML may include an emissive layer EML and the functional layer FNL having a larger area than the emissive layer EML. The light-emitting element LD may include the intermediate layer IML having one or more suitable structures and is not limited thereto. For example, the functional layer FNL may include a plurality of layers or may include two or more layers spaced and/or apart (e.g., spaced apart or separated) from each other (or one another) with the emissive layer EML therebetween.

The emissive layer EML may include an organic luminescent material. In one or more embodiments, the emissive layer EML may include an inorganic luminescent material or may be provided as a mixed layer of an organic luminescent material and an inorganic luminescent material. In this embodiment, the emissive layers EML included in the adjacent light-emitting parts EP1, EP2, and EP3 (refer to FIG. 5) may include luminescent materials that display different colors. For example, the emissive layer EML included in each of the light-emitting parts EP1, EP2, and EP3 may provide one of red light, green light, and/or blue light. However, without being limited thereto, the emissive layers EML arranged at all of the light-emitting parts EP1, EP2, and EP3 may include a luminescent material that displays the same color. For example, the emissive layers EML may provide blue light and/or white light.

The functional layer FNL may be arranged between the first electrode EL1 and the second electrode EL2. For example, the functional layer FNL may include a first intermediate functional layer arranged between the first electrode EL1 and the emissive layer EML and a second intermediate functional layer arranged between the second electrode EL2 and the emissive layer EML. In one or more embodiments of the present disclosure, one of the first intermediate functional layer and the second intermediate functional layer may not be provided. In this embodiment, the emissive layer EML is illustrated as being inserted into the functional layer FNL. For example, it may be understood that the emissive layer EML is arranged between the first intermediate functional layer and the second intermediate functional layer.

The functional layer FNL may control the movement of charges between the first electrode EL1 and the second electrode EL2. For example, the first intermediate functional layer may include a hole injection/transport material and/or an electron injection/transport material. The second intermediate functional layer may include at least one of an electron blocking layer, a hole transport layer, a hole injection layer, a hole blocking layer, an electron transport layer, an electron injection layer, and/or a charge generation layer.

The second electrode EL2 may be arranged on the intermediate layer IML. As described above, the second electrode EL2 may be connected to the connecting electrode CNE and may be electrically connected to the conductive pattern CP. For example, the second electrode EL2 may be electrically connected with the power supply voltage (e.g., the second drive voltage) ELVSS (refer to FIG. 4) through the connecting electrode CNE.

If (e.g., when) the light-emitting element LD has a tandem structure, lateral leakage current may occur between adjacent pixels, and if (e.g., when) the display panel DP includes some separators, the resistance of a separator area may be increased so that a power supply voltage drop (e.g., IR Drop) may occur. According to the present disclosure, the groove GV may be defined at the display panel DP, and thus the intermediate layer IML and the second electrode EL2 may be disconnected for each pixel. Accordingly, the lateral leakage current may be reduced or eliminated. The second electrode EL2 may be connected with the power supply voltage ELVSS through the conductive pattern CP, and thus the power supply voltage drop (IR Drop) may be reduced or eliminated.

The thin film encapsulation layer TFE may be arranged on the light-emitting element layer DP-OLED. The thin film encapsulation layer TFE may cover the light-emitting element LD and may cover the groove GV. The thin film encapsulation layer TFE may include a first inorganic layer IL1, an organic layer OL, and a second inorganic layer IL2 sequentially stacked one above another. However, without being limited thereto, the thin film encapsulation layer TFE may further include a plurality of inorganic layers and a plurality of organic layers.

The first inorganic layer IL1 and the second inorganic layer IL2 may protect the light-emitting element LD from moisture and/or oxygen outside the display panel DP, and the organic layer OL may protect the light-emitting element LD from foreign matter such as particles remaining in the process of forming the first inorganic layer IL1. The first inorganic layer IL1 and the second inorganic layer IL2 may include a silicon nitride layer, a silicon oxy nitride layer, a silicon oxide layer, a titanium oxide layer, and/or an aluminum oxide layer. The organic layer OL may include an acrylic organic layer, but the present disclosure is not limited thereto.

FIG. 7 is an enlarged sectional view of a partial area of the display panel DP according to one or more embodiments of the present disclosure. FIG. 7 illustrates an enlarged sectional view of area AA′ of FIG. 6.

Referring to FIGS. 6 and 7, the connecting electrode CNE may include the first connecting electrode layer LL1 arranged on the pixel defining layer PDL and the second connecting electrode layer LL2 arranged on the first connecting electrode layer LL1. The second connecting electrode layer LL2 may cover the first connecting electrode layer LL1. For example, the second connecting electrode layer LL2 may be formed to cover the upper surface and the side surface S_LL1 of the first connecting electrode layer LL1. Accordingly, the side surface S_LL1 of the first connecting electrode layer LL1 may not be exposed to the outside. The end of the first connecting electrode layer LL1 and the end of the second connecting electrode layer LL2 that covers the end of the first connecting electrode layer LL1 may constitute the tip portion TP of the connecting electrode CNE.

The second connecting electrode layer LL2 may be subjected to patterning by the end of the first connecting electrode layer LL1, and a portion of the second connecting electrode layer LL2 may be arranged at (e.g., in) the groove GV. Because the second connecting electrode layer LL2 is arranged on the first connecting electrode layer LL1 and subjected to patterning, the tip portion TP of the connecting electrode CNE may have an inverted tapered shape. For example, the taper angle formed by the lower surface of the first connecting electrode layer LL1 and the side surface S_LL1 of the first connecting electrode layer LL1 may be an acute angle or a right angle. Because the second connecting electrode layer LL2 is subjected to patterning by the protruding end of the first connecting electrode layer LL1, the second connecting electrode layer LL2 may gently be around (e.g., surround) the side surface S_LL1 of the first connecting electrode layer LL1, and the tip portion TP of the connecting electrode CNE may have an inverted tapered shape.

The first connecting electrode layer LL1 and the second connecting electrode layer LL2 may include transparent conductive oxide (TCO) such as indium tin oxide (e.g., ITO), indium zinc oxide (e.g., IZO), indium gallium zinc oxide (e.g., IGZO), zinc oxide (e.g., ZnO), and/or indium oxide (e.g., In₂O₃). However, the material constituting the first connecting electrode layer LL1 and the second connecting electrode layer LL2 is not limited thereto.

The intermediate layer IML may be arranged on the second connecting electrode layer LL2. The intermediate layer IML may be formed to cover the upper surface and a portion of the side surface S_LL2 of the second connecting electrode layer LL2. The intermediate layer IML may be subjected to patterning by the tip portion TP of the connecting electrode CNE, and a portion of the intermediate layer IML may be arranged at (e.g., in) the groove GV.

The second electrode EL2 may be arranged on the intermediate layer IML. The second electrode EL2 may be formed to cover the upper surface and the side surface S_IML of the intermediate layer IML. The second electrode EL2 may be subjected to patterning by the tip portion TP of the connecting electrode CNE, and a portion of the second electrode EL2 may be arranged at (e.g., in) the groove GV. The second electrode EL2 may be connected with (e.g., brought into contact with) the second connecting electrode layer LL2. For example, the end of the second electrode EL2 and a portion of the end of the second connecting electrode layer LL2 not being covered by the intermediate layer IML may be connected with (e.g., brought into contact with) each other at the tip portion TP of the connecting electrode CNE.

The dummy patterns DMP may be arranged at (e.g., in) the groove GV. The dummy patterns DMP may include a first split pattern PP1, a second split pattern PP2, and a third split pattern PP3.

The first split pattern PP1 may include the same material as the second connecting electrode layer LL2. The first split pattern PP1 may be concurrently (e.g., simultaneously) formed with the second connecting electrode layer LL2 through one process and may be separated from the second connecting electrode layer LL2 by the end of the first connecting electrode layer LL1.

The second split pattern PP2 may include the same material as the intermediate layer IML. The second split pattern PP2 may be concurrently (e.g., simultaneously) formed with the intermediate layer IML through one process and may be separated from the intermediate layer IML by the tip portion TP of the connecting electrode CNE.

The third split pattern PP3 may include the same material as the second electrode EL2. The third split pattern PP3 may be concurrently (e.g., simultaneously) formed with the second electrode EL2 through one process and may be separated from the second electrode EL2 by the tip portion TP of the connecting electrode CNE. In this case, the first split pattern PP1 and the third split pattern PP3 may be electrically connected in the groove GV.

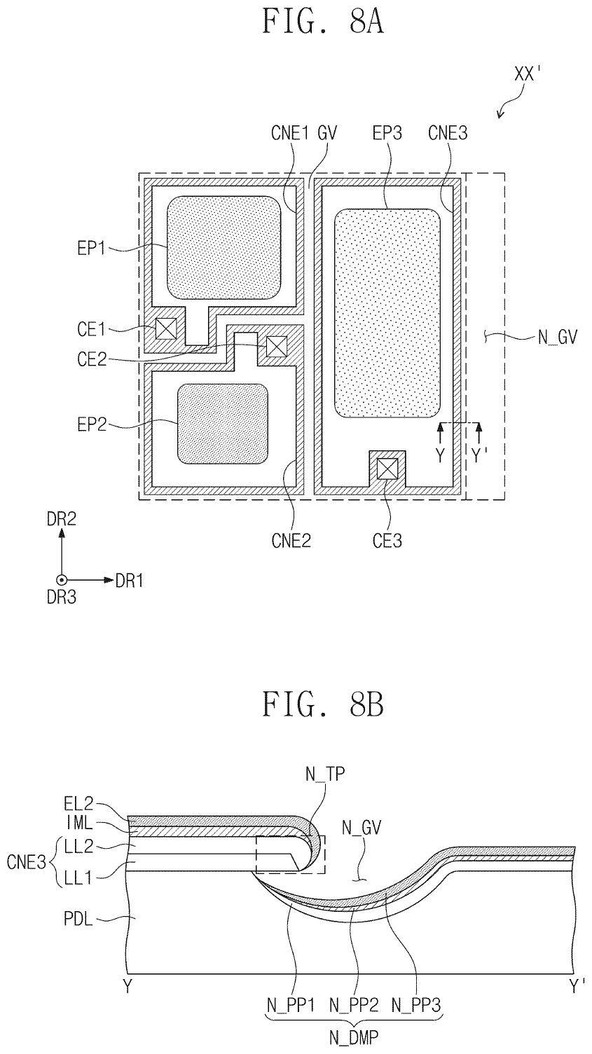

FIG. 8A is an enlarged plan view of a partial area of the display panel DP (refer to FIG. 3) according to one or more embodiments of the present disclosure, and FIG. 8B is an enlarged sectional view of a partial area of the display panel DP according to one or more embodiments of the present disclosure. FIG. 8A illustrates an enlarged plan view of area XX′ of FIG. 3, and FIG. 8B illustrates a sectional view taken along the line Y-Y′ of FIG. 8A. FIGS. 8A and 8B illustrate an outer region of the display panel DP.

Referring to FIGS. 8A and 8B, the connecting electrode CNE may not be arranged at the boundary between the display area DA (refer to FIG. 3) and the non-display area NDA (refer to FIG. 3) of the display panel DP. For example, a portion of the tip portion TP of the connecting electrode CNE may not be formed at the outer region of the display panel DP. For example, a tip portion N_TP (hereinafter, referred to as the outer tip portion) of the connecting electrode CNE formed at the outer region of the display panel DP may be formed adjacent to the area where the light-emitting parts EP1, EP2, and EP3 are arranged and may not be formed at the area where the light-emitting parts EP1, EP2, and EP3 are not arranged. An outer groove N_GV may be formed at the area where the outer tip portion N_TP is not formed. The outer groove N_GV may be formed along the boundary between the display area DA and the non-display area NDA. The outer groove N_GV may have a shape connected with the groove GV formed between the light-emitting parts EP1, EP2, and EP3.

Outer dummy patterns N_DMP may be arranged at the outer groove N_GV. The outer dummy patterns N_DMP may include a first outer split pattern N_PP1, a second outer split pattern N_PP2, and a third outer split pattern N_PP3.

The first outer split pattern N_PP1 may include the same material as the second connecting electrode layer LL2. The first outer split pattern N_PP1 may be concurrently (e.g., simultaneously) formed with the second connecting electrode layer LL2 through one process and may be separated from the second connecting electrode layer LL2 by the end of the first connecting electrode layer LL1. The first outer split pattern N_PP1 may have a one-body shape connected with the first split pattern PP1.

The second outer split pattern N_PP2 may include the same material as the intermediate layer IML. The second outer split pattern N_PP2 may be concurrently (e.g., simultaneously) formed with the intermediate layer IML through one process and may be separated from the intermediate layer IML by the outer tip portion N_TP of the connecting electrode CNE. The second outer split pattern N_PP2 may have a one-body shape connected with the second split pattern PP2.

The third outer split pattern N_PP3 may include the same material as the second electrode EL2. The third outer split pattern N_PP3 may be concurrently (e.g., simultaneously) formed with the second electrode EL2 through one process and may be separated from the second electrode EL2 by the outer tip portion N_TP of the connecting electrode CNE. The third outer split pattern N_PP3 may have a one-body shape connected with the third split pattern PP3.

The power supply voltage (e.g., the second drive voltage) ELVSS (refer to FIG. 4), which is a constant voltage, may be applied to the third outer split pattern N_PP3. The first outer split pattern N_PP1 and the third outer split pattern N_PP3 may be electrically connected in the outer groove N_GV. Accordingly, the second drive voltage ELVSS may be applied to the first outer split pattern N_PP1. Because the outer groove N_GV has a shape connected with the groove GV formed between the light-emitting parts EP1, EP2, and EP3, the second drive voltage ELVSS may be applied to the first split pattern PP1 and the third split pattern PP3 arranged at (e.g., in) the groove GV.

In one or more embodiments, because the second drive voltage ELVSS, which is a constant voltage, is applied to the first split pattern PP1 and the first outer split pattern N_PP1, noise coupling generated by the first split pattern PP1 and the first outer split pattern N_PP1 may be reduced or eliminated.

FIG. 9 is an enlarged sectional view of a partial area of the display panel DP according to one or more embodiments of the present disclosure. FIG. 9 illustrates an enlarged sectional view of area AA′ of FIG. 6. Hereinafter, in describing FIG. 9, components substantially identical or similar to the components described with reference to FIGS. 1 to 8B will be assigned with substantially identical or similar reference numerals, and repetitive descriptions will not be provided.

Referring to FIGS. 6 and 9, the connecting electrode CNEa may be arranged on the pixel defining layer PDL. The connecting electrode CNEa may electrically connect the pixel driver PDC and the light-emitting element LD. The connecting electrode CNEa may include the first connecting electrode layer LL1 arranged on the pixel defining layer PDL. For example, the connecting electrode CNEa may correspond to a structure in which the second connecting electrode layer LL2 (refer to FIG. 7) is not provided from the connecting electrode CNE of FIG. 7. The end of the first connecting electrode layer LL1 may constitute a tip portion TPa of the connecting electrode CNEa. For example, the taper angle formed by the lower surface of the connecting electrode CNEa and the side surface of the connecting electrode CNEa may be an acute angle or a right angle. However, without being limited thereto, the tip portion TPa may have an inverted tapered shape.

The intermediate layer IML may be arranged on the first connecting electrode layer LL1. The intermediate layer IML may be formed to cover the upper surface and a portion of the side surface S_LL1 of the first connecting electrode layer LL1. The intermediate layer IML may be subjected to patterning by the tip portion TPa of the connecting electrode CNEa, and a portion of the intermediate layer IML may be arranged at (e.g., in) the groove GV.

The second electrode EL2 may be arranged on the intermediate layer IML. The second electrode EL2 may be formed to cover the upper surface and the side surface S_IML of the intermediate layer IML. The second electrode EL2 may be subjected to patterning by the tip portion TPa of the connecting electrode CNEa, and a portion of the second electrode EL2 may be arranged at (e.g., in) the groove GV. The second electrode EL2 may be connected with (e.g., brought into contact with) the first connecting electrode layer LL1. For example, the end of the second electrode EL2 and a portion of the end of the first connecting electrode layer LL1 not being covered by the intermediate layer IML may be connected with (e.g., brought into contact with) each other at the tip portion TPa of the connecting electrode CNEa.

Dummy patterns DMPa may be arranged at (e.g., in) the groove GV. The dummy patterns DMPa may include a first split pattern PP1a and a second split pattern PP2a.

The first split pattern PP1a may include the same material as the intermediate layer IML. The first split pattern PP1a may be concurrently (e.g., simultaneously) formed with the intermediate layer IML through one process and may be separated from the intermediate layer IML by the tip portion TPa of the connecting electrode CNEa.

The second split pattern PP2a may include the same material as the second electrode EL2. The second split pattern PP2a may be concurrently (e.g., simultaneously) formed with the second electrode EL2 through one process and may be separated from the second electrode EL2 by the tip portion TPa of the connecting electrode CNEa.

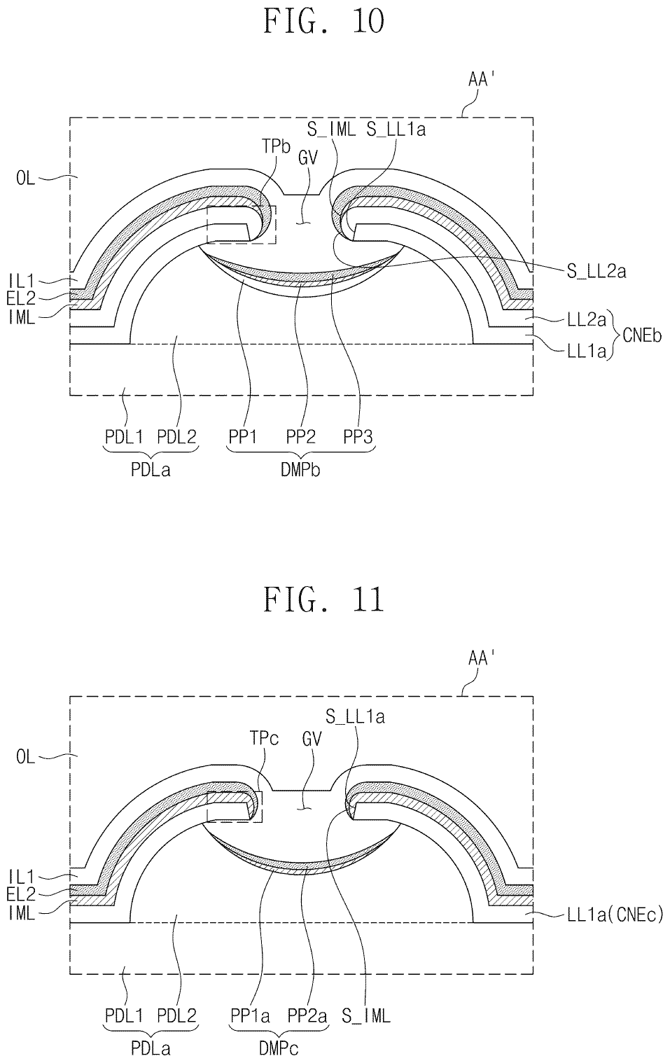

FIG. 10 is an enlarged sectional view of a partial area of the display panel DP according to one or more embodiments of the present disclosure. FIG. 10 illustrates an enlarged sectional view of area AA′ of FIG. 6. Hereinafter, in describing FIG. 10, components substantially identical or similar to the components described with reference to FIGS. 1 to 9 will be assigned with substantially identical or similar reference numerals, and repetitive descriptions will not be provided.

Referring to FIGS. 6 and 10, a pixel defining layer PDLa may include a first pixel defining layer portion PDL1 and a second pixel defining layer portion PDL2. The first pixel defining layer portion PDL1 and the second pixel defining layer portion PDL2 may be formed through one process and may have a one-body shape. The first pixel defining layer portion PDL1 may be arranged on the sixth insulating layer 60, and the second pixel defining layer portion PDL2 may be arranged on the first pixel defining layer portion PDL1. The first pixel defining layer portion PDL1 may correspond to the pixel defining layer PDL of FIG. 7. The second pixel defining layer portion PDL2 may have a shape partially protruding from the first pixel defining layer portion PDL1 in the thickness direction (e.g., the third direction DR3). The groove GV may be defined in the second pixel defining layer portion PDL2.

A connecting electrode CNEb may be arranged on the pixel defining layer PDLa. The connecting electrode CNEb may electrically connect the pixel driver PDC and the light-emitting element LD. The connecting electrode CNEb may include a first connecting electrode layer LL1a arranged on the pixel defining layer PDLa and a second connecting electrode layer LL2a arranged on the first connecting electrode layer LL1a. The second connecting electrode layer LL2a may cover the first connecting electrode layer LL1a. For example, the second connecting electrode layer LL2a may be formed to cover the upper surface and the side surface S_LL1a of the first connecting electrode layer LL1a. Accordingly, the side surface S_LL1a of the first connecting electrode layer LL1a may not be exposed to the outside. The end of the first connecting electrode layer LL1a and the end of the second connecting electrode layer LL2a that covers the end of the first connecting electrode layer LL1a may constitute a tip portion TPb of the connecting electrode CNEb.

The second connecting electrode layer LL2a may be subjected to patterning by the end of the first connecting electrode layer LL1a, and a portion of the second connecting electrode layer LL2a may be arranged at (e.g., in) the groove GV. Because the second connecting electrode layer LL2a is arranged on the first connecting electrode layer LL1a and subjected to patterning, the tip portion TPb of the connecting electrode CNEb may have an inverted tapered shape. For example, the taper angle formed by the lower surface of the first connecting electrode layer LL1a and the side surface S_LL1a of the first connecting electrode layer LL1a may be an acute angle or a right angle. Because the second connecting electrode layer LL2a is subjected to patterning by the protruding end of the first connecting electrode layer LL1a, the second connecting electrode layer LL2a may gently be (e.g., surround) the side surface S_LL1a of the first connecting electrode layer LL1a, and the tip portion TPb of the connecting electrode CNEb may have an inverted tapered shape. For example, in the present context, “gently surround” means to encircle or enclose something in a smooth, gradual, and non-abrupt manner. It implies that the second connecting electrode layer LL2a is arranged around the side surface S_LL1a of the first connecting electrode layer LL1a in a way that avoids sharp edges or sudden transitions. This smooth and gradual arrangement helps to ensure a stable and consistent connection, reducing the risk of mechanical stress or electrical interference. In addition, because the pixel defining layer PDLa includes the second pixel defining layer portion PDL2 protruding from the first pixel defining layer portion PDL1, the tip portion TPb of the connecting electrode CNEb may have an inverted tapered shape by the slope of the second pixel defining layer portion PDL2.

The first connecting electrode layer LL1a and the second connecting electrode layer LL2a may include transparent conductive oxide (TCO) such as indium tin oxide (e.g., ITO), indium zinc oxide (e.g., IZO), indium gallium zinc oxide (e.g., IGZO), zinc oxide (e.g., ZnO), and/or indium oxide (e.g., In₂O₃). However, the material constituting the first connecting electrode layer LL1a and the second connecting electrode layer LL2a is not limited thereto.

The intermediate layer IML may be arranged on the second connecting electrode layer LL2a. The intermediate layer IML may be formed to cover the upper surface and a portion of the side surface S_LL2a of the second connecting electrode layer LL2a. The intermediate layer IML may be subjected to patterning by the tip portion TPb of the connecting electrode CNEb, and a portion of the intermediate layer IML may be arranged at (e.g., in) the groove GV.

The second electrode EL2 may be arranged on the intermediate layer IML. The second electrode EL2 may be formed to cover the upper surface and the side surface S_IML of the intermediate layer IML. The second electrode EL2 may be subjected to patterning by the tip portion TPb of the connecting electrode CNEb, and a portion of the second electrode EL2 may be arranged at (e.g., in) the groove GV. The second electrode EL2 may be connected with (e.g., brought into contact with) the second connecting electrode layer LL2a. For example, the end of the second electrode EL2 and a portion of the end of the second connecting electrode layer LL2a not being covered by the intermediate layer IML may be connected with (e.g., brought into contact with) each other at the tip portion TPb of the connecting electrode CNEb.

Dummy patterns DMPb may be arranged at (e.g., in) the groove GV. The dummy patterns DMPb may include a first split pattern PP1, a second split pattern PP2, and a third split pattern PP3. The first split pattern PP1, the second split pattern PP2, and the third split pattern PP3 may be substantially the same as the first split pattern PP1, the second split pattern PP2, and the third split pattern PP3 of FIG. 7, respectively.

FIG. 11 is an enlarged sectional view of a partial area of the display panel DP according to one or more embodiments of the present disclosure. FIG. 11 illustrates an enlarged sectional view of area AA′ of FIG. 6. Hereinafter, in describing FIG. 11, components substantially identical or similar to the components described with reference to FIGS. 1 to 10 will be assigned with substantially identical or similar reference numerals, and repetitive descriptions will not be provided.

Referring to FIGS. 6 and 11, a pixel defining layer PDLa may include a first pixel defining layer portion PDL1 and a second pixel defining layer portion PDL2. A connecting electrode CNEc may be arranged on the pixel defining layer PDLa. The connecting electrode CNEc may electrically connect the pixel driver PDC and the light-emitting element LD. The connecting electrode CNEc may include a first connecting electrode layer LL1a arranged on the pixel defining layer PDLa. For example, the connecting electrode CNEc may correspond to a structure in which the second connecting electrode layer LL2a (refer to FIG. 10) is not provided from the connecting electrode CNEb of FIG. 10. The end of the first connecting electrode layer LL1a may constitute a tip portion TPc of the connecting electrode CNEc. For example, the taper angle formed by the lower surface of the connecting electrode CNEc and the side surface of the connecting electrode CNEc may be an acute angle or a right angle. However, without being limited thereto, the tip portion TPc may have an inverted tapered shape. For example, because the pixel defining layer PDLa includes the second pixel defining layer portion PDL2 protruding from the first pixel defining layer portion PDL1, the tip portion TPc of the connecting electrode CNEc may have an inverted tapered shape by the slope of the second pixel defining layer portion PDL2.

The intermediate layer IML may be arranged on the first connecting electrode layer LL1a. The intermediate layer IML may be formed to cover the upper surface and a portion of the side surface S_LL1a of the first connecting electrode layer LL1a. The intermediate layer IML may be subjected to patterning by the tip portion TPc of the connecting electrode CNEc, and a portion of the intermediate layer IML may be arranged at (e.g., in) the groove GV.

The second electrode EL2 may be arranged on the intermediate layer IML. The second electrode EL2 may be formed to cover the upper surface and the side surface S_IML of the intermediate layer IML. The second electrode EL2 may be subjected to patterning by the tip portion TPc of the connecting electrode CNEc, and a portion of the second electrode EL2 may be arranged at (e.g., in) the groove GV. The second electrode EL2 may be connected with (e.g., brought into contact with) the first connecting electrode layer LL1a. For example, the end of the second electrode EL2 and a portion of the end of the first connecting electrode layer LL1a not being covered by the intermediate layer IML may be connected with (e.g., brought into contact with) each other at the tip portion TPc of the connecting electrode CNEc.

Dummy patterns DMPc may be arranged at (e.g., in) the groove GV. The dummy patterns DMPc may include a first split pattern PP1a and a second split pattern PP2a. The first split pattern PP1a and the second split pattern PP2a may be substantially the same as the first split pattern PP1a and the second split pattern PP2a of FIG. 9, respectively.

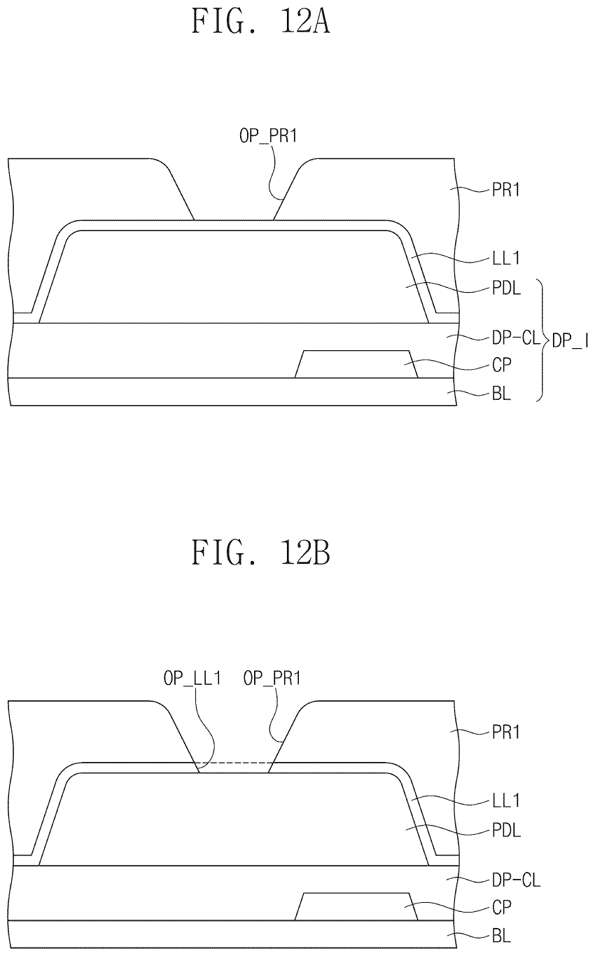

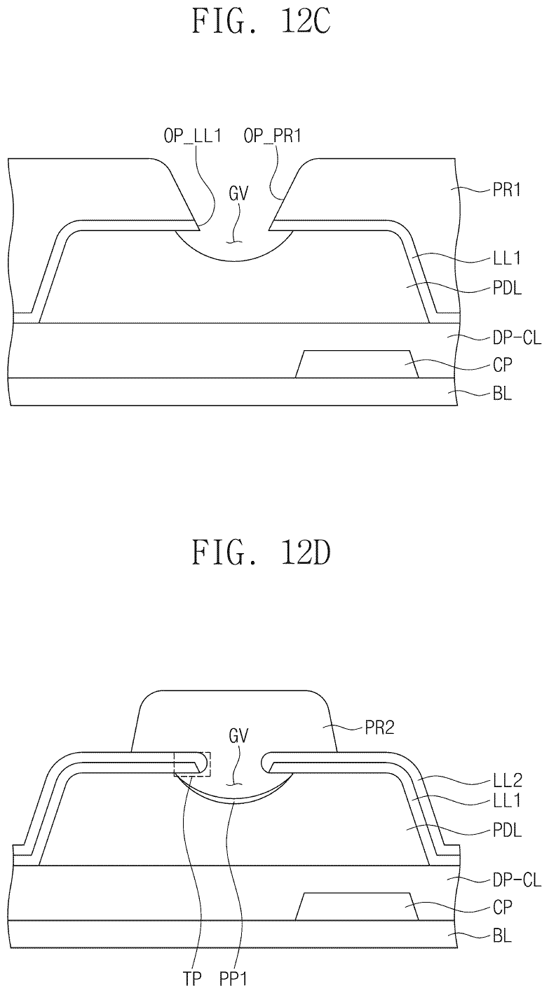

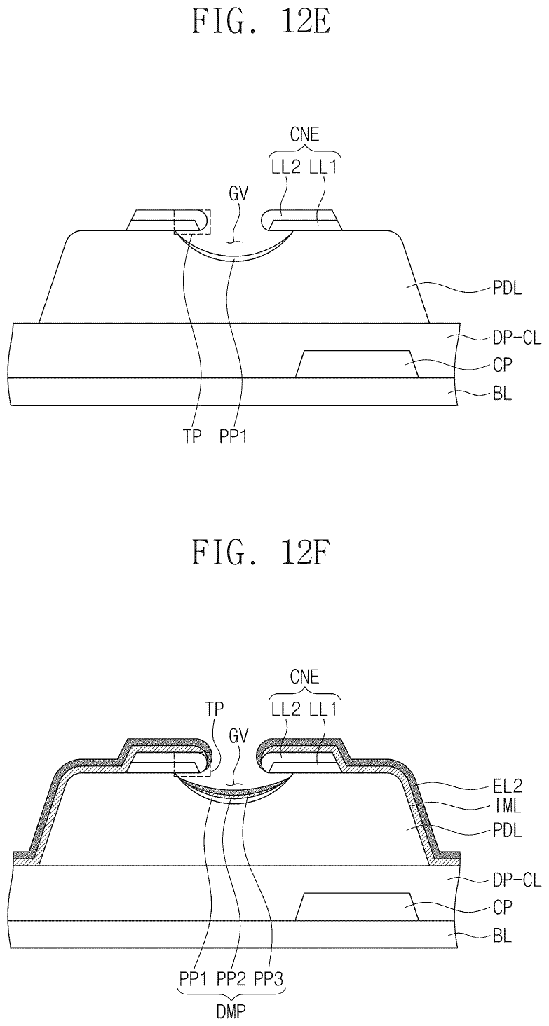

FIGS. 12A to 12F are sectional views illustrating some of the steps (e.g., acts or tasks) of a display panel manufacturing method according to one or more embodiments of the present disclosure. In describing FIGS. 12A to 12F, components substantially identical or similar to the components described with reference to FIGS. 1 to 8B will be assigned with substantially identical or similar reference numerals, and repetitive descriptions will not be provided. A display panel formed by the display panel manufacturing method of FIGS. 12A to 12F may correspond to FIG. 7.

In one or more embodiments, the display panel manufacturing method may include a step (e.g., act or task) of preparing a preliminary display panel including a base layer, a drive element layer that is arranged on the base layer and that includes a pixel driver including a power supply voltage, a conductive pattern arranged at the drive element layer and electrically connected with the power supply voltage, and a pixel defining layer arranged on the drive element layer, a step (e.g., act or task) of depositing, on the preliminary display panel, a first connecting electrode layer connected to the conductive pattern, a step (e.g., act or task) of forming a groove of the pixel defining layer overlapping a portion of the first connecting electrode layer by etching a portion of the first connecting electrode layer and a portion of the pixel defining layer, a step (e.g., act or task) of forming a connecting electrode by etching the first connecting electrode layer, and a step (e.g., act or task) of forming, on the connecting electrode and the pixel defining layer, an intermediate layer and a cathode connected to the connecting electrode.

Referring to FIG. 12A, the display panel manufacturing method of the present disclosure may include the step (e.g., act or task) of preparing the preliminary display panel DP_I and the step (e.g., act or task) of depositing the first connecting electrode layer LL1. The preliminary display panel DP_I may include the base layer BL, the drive element layer DP-CL arranged on the base layer BL, the conductive pattern CP arranged at (e.g., in) the drive element layer DP-CL, and the pixel defining layer PDL arranged on the drive element layer DP-CL.

The base layer BL may be a member that provides the base surface on which the pixel driver PDC (refer to FIG. 6) is arranged. The drive element layer DP-CL may be formed through a suitable circuit element manufacturing process of forming an insulating layer, a semiconductor layer, and a conductive layer by coating, deposition, and/or the like and forming a semiconductor pattern, a conductive pattern, and a signal line by selectively making the insulating layer, the semiconductor layer, and the conductive layer subject to patterning by a photolithography process and an etching process. The drive element layer DP-CL may include the first to sixth insulating layers 10, 20, 30, 40, 50, and 60 sequentially stacked on the base layer BL and the pixel driver PDC. The pixel driver PDC may include the power supply voltage (e.g., the second drive voltage) ELVSS (refer to FIG. 4). The conductive pattern CP may be electrically connected with the second drive voltage ELVSS of the pixel driver PDC.

The pixel defining layer PDL may be arranged on the drive element layer DP-CL. The pixel defining layer PDL having the light-emitting opening OP-PDL (refer to FIG. 6) and the through-hole OP-P (refer to FIG. 6) defined therein may be formed by depositing a preliminary pixel defining layer on the drive element layer DP-CL and selectively making the preliminary pixel defining layer subject to patterning through a photolithography process and an etching process.

The first connecting electrode layer LL1 may be deposited on (e.g., formed on) the preliminary display panel DP_I. The step (e.g., act or task) of depositing the first connecting electrode layer LL1 may be performed by a process of depositing a conductive material. The conductive material forming the first connecting electrode layer LL1 may include transparent conductive oxide (TCO) such as indium tin oxide (e.g., ITO), indium zinc oxide (e.g., IZO), indium gallium zinc oxide (e.g., IGZO), zinc oxide (e.g., ZnO), and/or indium oxide (e.g., In₂O₃). However, the material constituting the first connecting electrode layer LL1 is not limited thereto. The deposited first connecting electrode layer LL1 may be connected to the conductive pattern CP.

The display panel manufacturing method of the present disclosure may include a step (e.g., act or task) of forming a first photoresist layer PR1. The first photoresist layer PR1 may be formed on the first connecting electrode layer LL1. The first photoresist layer PR1 may be formed by forming a preliminary photoresist layer on the first connecting electrode layer LL1 and thereafter making the preliminary photoresist layer subject to patterning utilizing a photo mask. The first photoresist layer PR1 including a first photo opening OP_PR1 may be formed through the patterning process.

Referring to FIGS. 12B and 12C, the display panel manufacturing method of the present disclosure may include the step (e.g., act or task) of forming the groove GV of the pixel defining layer PDL overlapping a portion of the first connecting electrode layer LL1 by etching a portion of the first connecting electrode layer LL1 and a portion of the pixel defining layer PDL.

Referring to FIG. 12B, the step (e.g., act or task) of forming the groove GV of the pixel defining layer PDL may include a step (e.g., act or task) of etching a portion of the first connecting electrode layer LL1. The step (e.g., act or task) of etching the first connecting electrode layer LL1 may be performed through wet etching. The etched portion of the first connecting electrode layer LL1 may be removed to form a first opening OP_LL1 in the first connecting electrode layer LL1. The first opening OP_LL1 may overlap the first photo opening OP_PR1 of the first photoresist layer PR1. The end of the first connecting electrode layer LL1 that defines the first opening OP_LL1 may have a tapered shape. For example, the taper angle formed by the lower surface of the first connecting electrode layer LL1 and the side surface of the first connecting electrode layer LL1 may be an acute angle or a right angle. However, the present disclosure is not limited thereto.

Referring to FIG. 12C, the step (e.g., act or task) of forming the groove GV of the pixel defining layer PDL may include a step (e.g., act or task) of etching a portion of the pixel defining layer PDL. The step (e.g., act or task) of etching the pixel defining layer PDL may be performed through dry etching. The etched portion of the pixel defining layer PDL may be removed to form the groove GV in the pixel defining layer PDL. The groove GV may overlap the first opening OP_LL1 of the first connecting electrode layer LL1 and the first photo opening OP_PR1 of the first photoresist layer PR1. The groove GV may overlap a portion of the first connecting electrode layer LL1. For example, a portion of the first connecting electrode layer LL1 may protrude from the end of the groove GV toward the center of the groove GV.

Referring to FIG. 12D, the display panel manufacturing method of the present disclosure may include a step (e.g., act or task) of depositing the second connecting electrode layer LL2 and a step (e.g., act or task) of forming the tip portion TP after the removal of the first photoresist layer PR1 (refer to FIG. 12C).

The second connecting electrode layer LL2 may be deposited on (e.g., formed on) the first connecting electrode layer LL1. The step (e.g., act or task) of depositing the second connecting electrode layer LL2 may be performed by a process of depositing a conductive material. The conductive material forming the second connecting electrode layer LL2 may include transparent conductive oxide (TCO) such as indium tin oxide (e.g., ITO), indium zinc oxide (e.g., IZO), indium gallium zinc oxide (e.g., IGZO), zinc oxide (e.g., ZnO), and/or indium oxide (e.g., In₂O₃). However, the material constituting the second connecting electrode layer LL2 is not limited thereto. The tip portion TP may be defined by the end of the first connecting electrode layer LL1 and the end of the second connecting electrode layer LL2 that covers the end of the first connecting electrode layer LL1.

The second connecting electrode layer LL2 may be subjected to patterning by the end of the first connecting electrode layer LL1, and a portion of the second connecting electrode layer LL2 may be arranged at (e.g., in) the groove GV. A portion of the second connecting electrode layer LL2 separated from the second connecting electrode layer LL2 by the end of the first connecting electrode layer LL1 may be defined as the first split pattern PP1. The first split pattern PP1 may include the same material as the second connecting electrode layer LL2. The first split pattern PP1 may be concurrently (e.g., simultaneously) formed with the second connecting electrode layer LL2 through one process.

The display panel manufacturing method of the present disclosure may include a step (e.g., act or task) of forming a second photoresist layer PR2. The second photoresist layer PR2 may be formed on the second connecting electrode layer LL2. The second photoresist layer PR2 may be formed by forming a preliminary photoresist layer on the second connecting electrode layer LL2 and thereafter making the preliminary photoresist layer subject to patterning utilizing a photo mask. The second photoresist layer PR2 overlapping the groove GV may be formed through the patterning process.

Referring to FIG. 12E, the display panel manufacturing method of the present disclosure may include the step (e.g., act or task) of forming the connecting electrode CNE by etching the first connecting electrode layer LL1 and the second connecting electrode layer LL2. The step (e.g., act or task) of etching the first connecting electrode layer LL1 and the second connecting electrode layer LL2 may be performed through wet etching. Portions of the first connecting electrode layer LL1 and the second connecting electrode layer LL2 that do not overlap the second photoresist layer PR2 (refer to FIG. 12D) may be etched and removed. The first connecting electrode layer LL1 and the second connecting electrode layer LL2 that overlap the second photoresist layer PR2 and remain may form the connecting electrode CNE. Thereafter, the second photoresist layer PR2 may be removed.

Referring to FIG. 12F, the display panel manufacturing method of the present disclosure may include the step (e.g., act or task) of forming, on the connecting electrode CNE and the pixel defining layer PDL, the intermediate layer IML and the second electrode EL2 (e.g., the cathode) connected to the connecting electrode CNE. The step (e.g., act or task) of forming the intermediate layer IML and the step (e.g., act or task) of forming the second electrode EL2 may each be performed through a deposition process. For example, the step (e.g., act or task) of forming the cathode EL2 may include a step (e.g., act or task) of depositing the cathode EL2 disconnected by the groove GV and connected with the second connecting electrode layer LL2.

The intermediate layer IML may be subjected to patterning by the tip portion TP of the connecting electrode CNE, and a portion of the intermediate layer IML may be arranged at (e.g., in) the groove GV. A portion of the intermediate layer IML separated from the intermediate layer IML by the tip portion TP of the connecting electrode CNE may be defined as the second split pattern PP2. The second split pattern PP2 may include the same material as the intermediate layer IML. The second split pattern PP2 may be concurrently (e.g., simultaneously) formed with the intermediate layer IML through one process.

The second electrode EL2 may be subjected to patterning by the tip portion TP of the connecting electrode CNE, and a portion of the second electrode EL2 may be arranged at (e.g., in) the groove GV. The second electrode EL2 may be connected with (e.g., brought into contact with) the second connecting electrode layer LL2. For example, the end of the second electrode EL2 and a portion of the end of the second connecting electrode layer LL2 not being covered by the intermediate layer IML may be connected with (e.g., brought into contact with) each other at the tip portion TP of the connecting electrode CNE. The second electrode EL2 may be connected to the conductive pattern CP through the connecting electrode CNE, and the conductive pattern CP may electrically connect the power supply voltage (e.g., the second drive voltage) ELVSS (refer to FIG. 4) and the second electrode EL2.

A portion of the second electrode EL2 separated from the second electrode EL2 by the tip portion TP of the connecting electrode CNE may be defined as the third split pattern PP3. The third split pattern PP3 may include the same material as the second electrode EL2. The third split pattern PP3 may be concurrently (e.g., simultaneously) formed with the second electrode EL2 through one process. The first split pattern PP1, the second split pattern PP2, and the third split pattern PP3 may form the dummy patterns DMP.

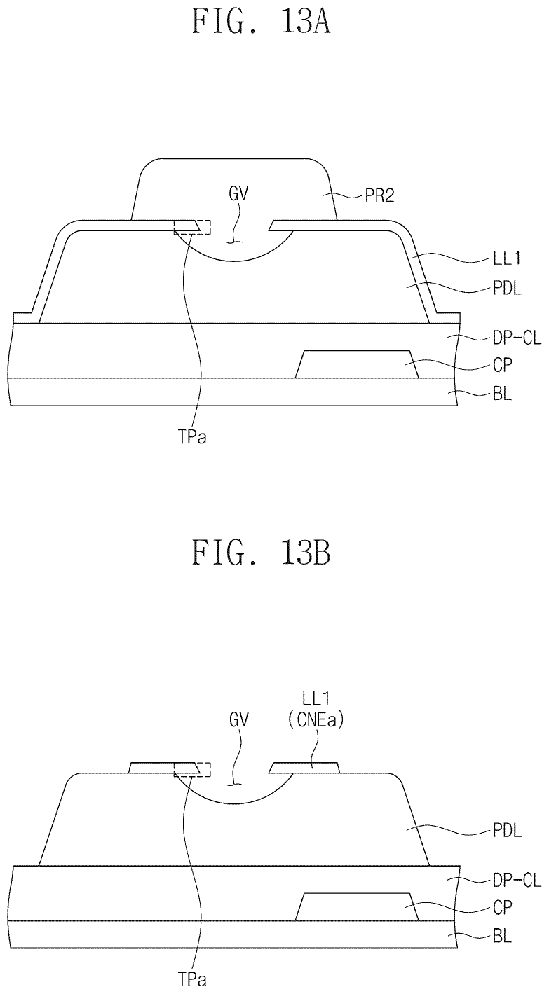

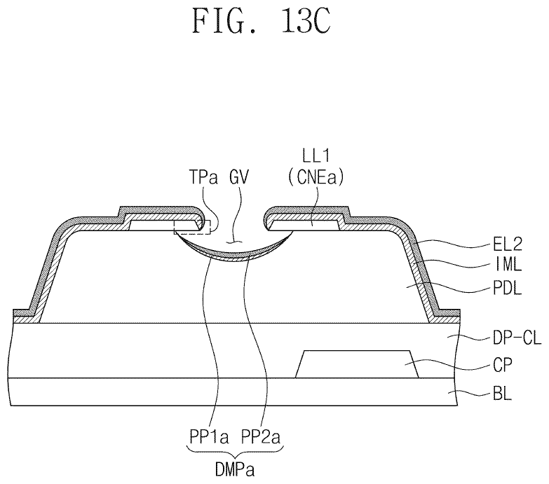

FIGS. 13A to 13C are sectional views illustrating some of the steps (e.g., acts or tasks) of a display panel manufacturing method according to one or more embodiments of the present disclosure. In describing FIGS. 13A to 13C, components substantially identical or similar to the components described with reference to FIGS. 1 to 12F will be assigned with substantially identical or similar reference numerals, and repetitive descriptions will not be provided. A display panel formed by the display panel manufacturing method of FIGS. 13A to 13C may correspond to FIG. 9.

In one or more embodiments, the display panel manufacturing method may include a step (e.g., act or task) of preparing the preliminary display panel DP_I (refer to FIG. 12A), a step (e.g., act or task) of depositing the first connecting electrode layer LL1, and a step (e.g., act or task) of forming the groove GV of the pixel defining layer PDL that overlaps a portion of the first connecting electrode layer LL1. The step (e.g., act or task) of preparing the preliminary display panel DP_I (refer to FIG. 12A), the step (e.g., act or task) of depositing the first connecting electrode layer LL1, and the step (e.g., act or task) of forming the groove GV of the pixel defining layer PDL that overlaps the portion of the first connecting electrode layer LL1 may be substantially the same as those in FIGS. 12A to 12C.

Referring to FIG. 13A, the display panel manufacturing method of the present disclosure may include a step (e.g., act or task) of forming the tip portion TPa and a step (e.g., act or task) of forming a second photoresist layer PR2 after the removal of the first photoresist layer PR1 (refer to FIG. 12C). The tip portion TPa may be defined by the end of the first connecting electrode layer LL1.

The second photoresist layer PR2 may be formed on the first connecting electrode layer LL1. The second photoresist layer PR2 may be formed by forming a preliminary photoresist layer on the first connecting electrode layer LL1 and thereafter making the preliminary photoresist layer subject to patterning utilizing a photo mask. The second photoresist layer PR2 overlapping the groove GV may be formed through the patterning process.

Referring to FIG. 13B, the display panel manufacturing method of the present disclosure may include a step (e.g., act or task) of forming the connecting electrode CNEa by etching the first connecting electrode layer LL1. The step (e.g., act or task) of etching the first connecting electrode layer LL1 may be performed through wet etching. A portion of the first connecting electrode layer LL1 that does not overlap the second photoresist layer PR2 (refer to FIG. 13A) may be etched and removed, and the first connecting electrode layer LL1 that overlaps the second photoresist layer PR2 and remains may form the connecting electrode CNEa. Thereafter, the second photoresist layer PR2 may be removed.

Referring to FIG. 13C, the display panel manufacturing method of the present disclosure may include a step (e.g., act or task) of forming, on the connecting electrode CNEa and the pixel defining layer PDL, the intermediate layer IML and the second electrode EL2 (e.g., the cathode). The step (e.g., act or task) of forming the intermediate layer IML and the step (e.g., act or task) of forming the second electrode EL2 may each be performed through a deposition process. For example, the step (e.g., act or task) of forming the cathode EL2 may include a step (e.g., act or task) of depositing the cathode EL2 disconnected by the groove GV and connected with the first connecting electrode layer LL1.

The intermediate layer IML may be subjected to patterning by the tip portion TPa of the connecting electrode CNEa, and a portion of the intermediate layer IML may be arranged at (e.g., in) the groove GV. A portion of the intermediate layer IML separated from the intermediate layer IML by the tip portion TPa of the connecting electrode CNEa may be defined as the first split pattern PP1a. The first split pattern PP1a may include the same material as the intermediate layer IML. The first split pattern PP1a may be concurrently (e.g., simultaneously) formed with the intermediate layer IML through one process.

The second electrode EL2 may be subjected to patterning by the tip portion TPa of the connecting electrode CNEa, and a portion of the second electrode EL2 may be arranged at (e.g., in) the groove GV. The second electrode EL2 may be connected with (e.g., brought into contact with) the first connecting electrode layer LL1. For example, the end of the second electrode EL2 and a portion of the end of the first connecting electrode layer LL1 not being covered by the intermediate layer IML may be connected with (e.g., brought into contact with) each other at the tip portion TPa of the connecting electrode CNEa. The second electrode EL2 may be connected to the conductive pattern CP through the connecting electrode CNEa, and the conductive pattern CP may electrically connect the power supply voltage (e.g., the second drive voltage) ELVSS (refer to FIG. 4) and the second electrode EL2.

A portion of the second electrode EL2 separated from the second electrode EL2 by the tip portion TPa of the connecting electrode CNEa may be defined as the second split pattern PP2a. The second split pattern PP2a may include the same material as the second electrode EL2. The second split pattern PP2a may be concurrently (e.g., simultaneously) formed with the second electrode EL2 through one process. The first split pattern PP1a and the second split pattern PP2a may form the dummy patterns DMPa.

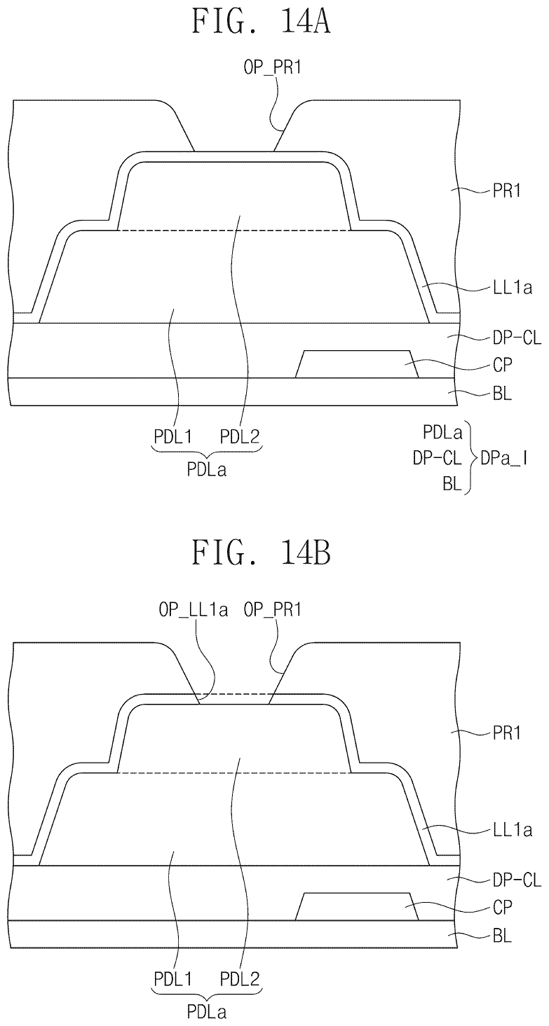

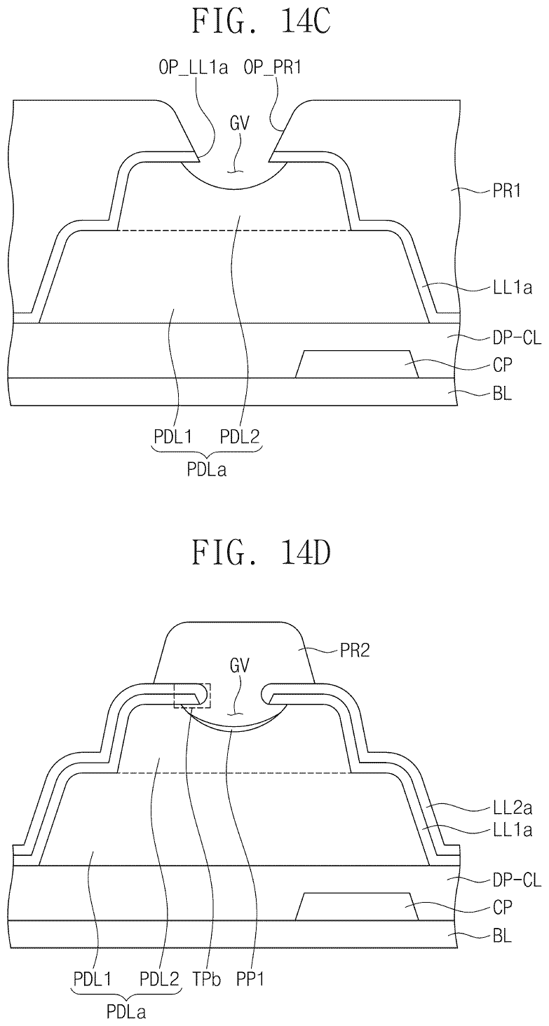

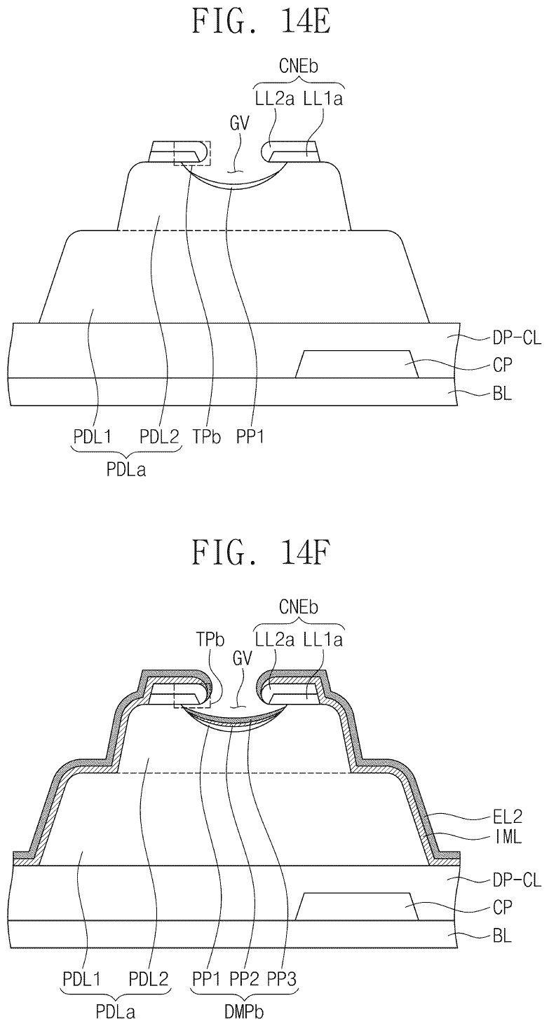

FIGS. 14A to 14F are sectional views illustrating some of the steps (e.g., acts or tasks) of a display panel manufacturing method according to one or more embodiments of the present disclosure. In describing FIGS. 14A to 14F, components substantially identical or similar to the components described with reference to FIGS. 1 to 12F will be assigned with substantially identical or similar reference numerals, and repetitive descriptions will not be provided. A display panel formed by the display panel manufacturing method of FIGS. 14A to 14F may correspond to FIG. 10.

Referring to FIG. 14A, the display panel manufacturing method of the present disclosure may include a step (e.g., act or task) of preparing a preliminary display panel DPa_I and a step (e.g., act or task) of depositing the first connecting electrode layer LL1a. The preliminary display panel DPa_I may include the base layer BL, the drive element layer DP-CL arranged on the base layer BL, the conductive pattern CP arranged at (e.g., in) the drive element layer DP-CL, and the pixel defining layer PDLa arranged on the drive element layer DP-CL.

The pixel defining layer PDLa may be formed on the drive element layer DP-CL. The pixel defining layer PDLa including the first pixel defining layer portion PDL1 and the second pixel defining layer portion PDL2 having a shape partially protruding from the first pixel defining layer portion PDL1 may be formed by depositing a preliminary pixel defining layer on the drive element layer DP-CL and selectively making the preliminary pixel defining layer subject to patterning by a photolithography process and an etching process. The first pixel defining layer portion PDL1 and the second pixel defining layer portion PDL2 may be formed through one process and may have a one-body shape. A half-tone mask may be utilized in the above process, but a method of forming the pixel defining layer PDLa is not limited thereto. In addition, the light-emitting opening OP-PDL (refer to FIG. 6) and the through-hole OP-P (refer to FIG. 6) may be defined at (e.g., in) the pixel defining layer PDLa.

The first connecting electrode layer LL1a may be deposited on (e.g., formed on) the preliminary display panel DPa_I. In more detail, the first connecting electrode layer LL1a may be deposited on the first pixel defining layer portion PDL1 and the second pixel defining layer portion PDL2 of the pixel defining layer PDLa. The step (e.g., act or task) of depositing the first connecting electrode layer LL1a may be performed by a process of depositing a conductive material. The conductive material forming the first connecting electrode layer LL1a may include transparent conductive oxide (TCO) such as indium tin oxide (e.g., ITO), indium zinc oxide (e.g., IZO), indium gallium zinc oxide (e.g., IGZO), zinc oxide (e.g., ZnO), and/or indium oxide (e.g., In₂O₃). However, the material constituting the first connecting electrode layer LL1a is not limited thereto.

The display panel manufacturing method of the present disclosure may include a step (e.g., act or task) of forming a first photoresist layer PR1. The first photoresist layer PR1 may be formed on the first connecting electrode layer LL1a. The first photoresist layer PR1 may be formed by forming a preliminary photoresist layer on the first connecting electrode layer LL1a and thereafter making the preliminary photoresist layer subject to patterning utilizing a photo mask. The first photoresist layer PR1 including a first photo opening OP_PR1 may be formed through the patterning process.

Referring to FIGS. 14B and 14C, the display panel manufacturing method of the present disclosure may include a step (e.g., act or task) of forming the groove GV of the pixel defining layer PDLa that overlaps a portion of the first connecting electrode layer LL1a.

Referring to FIG. 14B, the step (e.g., act or task) of forming the groove GV of the pixel defining layer PDLa may include a step (e.g., act or task) of etching a portion of the first connecting electrode layer LL1a. The step (e.g., act or task) of etching the first connecting electrode layer LL1a may be performed through wet etching. The etched portion of the first connecting electrode layer LL1a may be removed to form a first opening OP_LL1a in the first connecting electrode layer LL1a. The first opening OP_LL1a may overlap the first photo opening OP_PR1 of the first photoresist layer PR1. The end of the first connecting electrode layer LL1a that defines the first opening OP_LL1a may have a tapered shape. For example, the taper angle formed by the lower surface of the first connecting electrode layer LL1a and the side surface of the first connecting electrode layer LL1a may be an acute angle or a right angle. However, the present disclosure is not limited thereto.

Referring to FIG. 14C, the step (e.g., act or task) of forming the groove GV of the pixel defining layer PDLa may include a step (e.g., act or task) of etching a portion of the pixel defining layer PDLa. The step (e.g., act or task) of etching the pixel defining layer PDLa may be performed through dry etching. The etched portion of the pixel defining layer PDLa may be removed to form the groove GV in the pixel defining layer PDLa. The groove GV may overlap the first opening OP_LL1a of the first connecting electrode layer LL1a and the first photo opening OP_PR1 of the first photoresist layer PR1. The groove GV may overlap a portion of the first connecting electrode layer LL1a. For example, a portion of the first connecting electrode layer LL1a may protrude from the end of the groove GV toward the center of the groove GV.

Referring to FIG. 14D, the display panel manufacturing method of the present disclosure may include a step (e.g., act or task) of depositing the second connecting electrode layer LL2a and a step (e.g., act or task) of forming the tip portion TPb after the removal of the first photoresist layer PR1 (refer to FIG. 14C).

The second connecting electrode layer LL2a may be deposited on (e.g., formed on) the first connecting electrode layer LL1a. The step (e.g., act or task) of depositing the second connecting electrode layer LL2a may be performed by a process of depositing a conductive material. The conductive material forming the second connecting electrode layer LL2a may include transparent conductive oxide (TCO) such as indium tin oxide (e.g., ITO), indium zinc oxide (e.g., IZO), indium gallium zinc oxide (e.g., IGZO), zinc oxide (e.g., ZnO), and/or indium oxide (e.g., In₂O₃). However, the material constituting the second connecting electrode layer LL2a is not limited thereto. The tip portion TPb may be defined by the end of the first connecting electrode layer LL1a and the end of the second connecting electrode layer LL2a that covers the end of the first connecting electrode layer LL1a.

Because the second connecting electrode layer LL2a is subjected to patterning by the protruding end of the first connecting electrode layer LL1a, the second connecting electrode layer LL2a may gently be around (e.g., surround) the side surface S_LL1a of the first connecting electrode layer LL1a, and the tip portion TPb of the connecting electrode CNEb may have an inverted tapered shape. In addition, because the pixel defining layer PDLa includes the second pixel defining layer portion PDL2 protruding from the first pixel defining layer portion PDL1, the tip portion TPb of the connecting electrode CNEb may have an inverted tapered shape by the slope of the second pixel defining layer portion PDL2.

The second connecting electrode layer LL2a may be subjected to patterning by the end of the first connecting electrode layer LL1a, and a portion of the second connecting electrode layer LL2a may be arranged at (e.g., in) the groove GV. A portion of the second connecting electrode layer LL2a separated from the second connecting electrode layer LL2a by the end of the first connecting electrode layer LL1a may be defined as the first split pattern PP1. The first split pattern PP1 may include the same material as the second connecting electrode layer LL2a. The first split pattern PP1 may be concurrently (e.g., simultaneously) formed with the second connecting electrode layer LL2a through one process.

The display panel manufacturing method of the present disclosure may include a step (e.g., act or task) of forming a second photoresist layer PR2. The second photoresist layer PR2 may be formed on the second connecting electrode layer LL2a. The second photoresist layer PR2 may be formed by forming a preliminary photoresist layer on the second connecting electrode layer LL2a and thereafter making the preliminary photoresist layer subject to patterning utilizing a photo mask. The second photoresist layer PR2 overlapping the groove GV may be formed through the patterning process.

Referring to FIG. 14E, the display panel manufacturing method of the present disclosure may include a step (e.g., act or task) of forming the connecting electrode CNEb by etching the first connecting electrode layer LL1a and the second connecting electrode layer LL2a. The step (e.g., act or task) of etching the first connecting electrode layer LL1a and the second connecting electrode layer LL2a may be performed through wet etching. Portions of the first connecting electrode layer LL1a and the second connecting electrode layer LL2a that do not overlap the second photoresist layer PR2 (refer to FIG. 14D) may be etched and removed. The first connecting electrode layer LL1a and the second connecting electrode layer LL2a that overlap the second photoresist layer PR2 and remain may form the connecting electrode CNEb. Thereafter, the second photoresist layer PR2 may be removed.

Referring to FIG. 14F, the display panel manufacturing method of the present disclosure may include a step (e.g., act or task) of forming, on the connecting electrode CNEb and the pixel defining layer PDLa, the intermediate layer IML and the second electrode EL2 (e.g., the cathode). The step (e.g., act or task) of forming the intermediate layer IML and the step (e.g., act or task) of forming the second electrode EL2 may each be performed through a deposition process. For example, the step (e.g., act or task) of forming the cathode EL2 may include a step (e.g., act or task) of depositing the cathode EL2 disconnected by the groove GV and connected with the second connecting electrode layer LL2a.

The intermediate layer IML may be subjected to patterning by the tip portion TPb of the connecting electrode CNEb, and a portion of the intermediate layer IML may be arranged at (e.g., in) the groove GV. A portion of the intermediate layer IML separated from the intermediate layer IML by the tip portion TPb of the connecting electrode CNEb may be defined as the second split pattern PP2. The second split pattern PP2 may include the same material as the intermediate layer IML. The second split pattern PP2 may be concurrently (e.g., simultaneously) formed with the intermediate layer IML through one process.

The second electrode EL2 may be subjected to patterning by the tip portion TPb of the connecting electrode CNEb, and a portion of the second electrode EL2 may be arranged at (e.g., in) the groove GV. The second electrode EL2 may be connected with (e.g., brought into contact with) the second connecting electrode layer LL2a. For example, the end of the second electrode EL2 and a portion of the end of the second connecting electrode layer LL2a not being covered by the intermediate layer IML may be connected with (e.g., brought into contact with) each other at the tip portion TPb of the connecting electrode CNEb. The second electrode EL2 may be connected to the conductive pattern CP through the connecting electrode CNEb, and the conductive pattern CP may electrically connect the power supply voltage (e.g., the second drive voltage) ELVSS (refer to FIG. 4) and the second electrode EL2.

A portion of the second electrode EL2 separated from the second electrode EL2 by the tip portion TPb of the connecting electrode CNEb may be defined as the third split pattern PP3. The third split pattern PP3 may include the same material as the second electrode EL2. The third split pattern PP3 may be concurrently (e.g., simultaneously) formed with the second electrode EL2 through one process. The first split pattern PP1, the second split pattern PP2, and the third split pattern PP3 may form the dummy patterns DMPb.

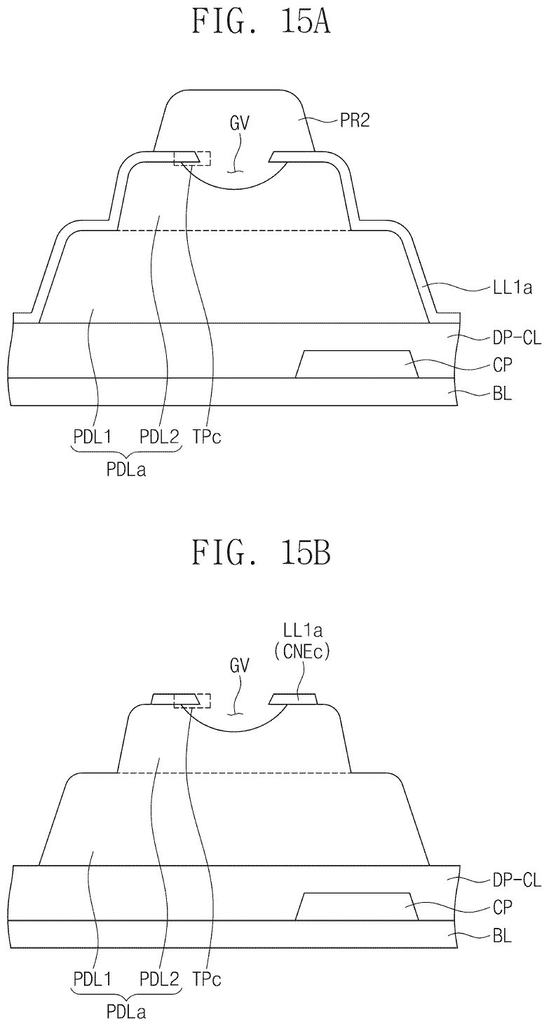

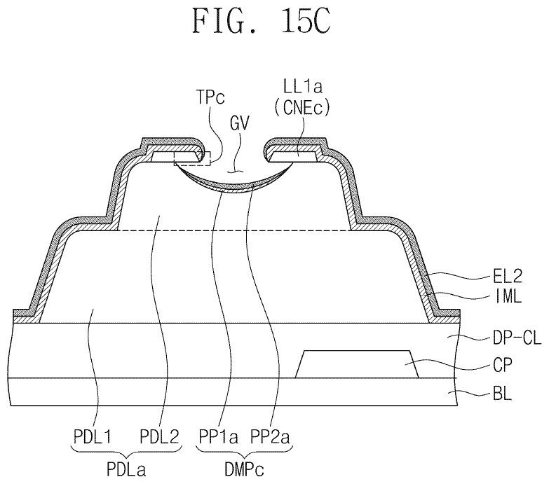

FIGS. 15A to 15C are sectional views illustrating some of the steps (e.g., acts or tasks) of a display panel manufacturing method according to one or more embodiments of the present disclosure. In describing FIGS. 15A to 15C, components substantially identical or similar to the components described with reference to FIGS. 1 to 14F will be assigned with substantially identical or similar reference numerals, and repetitive descriptions will not be provided. A display panel formed by the display panel manufacturing method of FIGS. 15A to 15C may correspond to FIG. 11.

In one or more embodiments, the display panel manufacturing method may include a step (e.g., act or task) of preparing the preliminary display panel DPa_I (refer to FIG. 14A), a step (e.g., act or task) of depositing the first connecting electrode layer LL1a, and a step (e.g., act or task) of forming the groove GV of the pixel defining layer PDLa that overlaps a portion of the first connecting electrode layer LL1a. The step (e.g., act or task) of preparing the preliminary display panel DPa_I, the step (e.g., act or task) of depositing the first connecting electrode layer LL1a, and step the (e.g., act or task) of forming the groove GV of the pixel defining layer PDLa that overlaps the portion of the first connecting electrode layer LL1a may be substantially the same as those in FIGS. 14A to 14C.

Referring to FIG. 15A, the display panel manufacturing method of the present disclosure may include a step (e.g., act or task) of forming the tip portion TPc and a step (e.g., act or task) of forming a second photoresist layer PR2 after the removal of the first photoresist layer PR1 (refer to FIG. 14C). The tip portion TPc may be defined by the end of the first connecting electrode layer LL1a.

Because the pixel defining layer PDLa includes the second pixel defining layer portion PDL2 protruding from the first pixel defining layer portion PDL1, the tip portion TPc of the connecting electrode CNEc may have an inverted tapered shape by the slope of the second pixel defining layer portion PDL2.

The second photoresist layer PR2 may be formed on the first connecting electrode layer LL1a. The second photoresist layer PR2 may be formed by forming a preliminary photoresist layer on the first connecting electrode layer LL1a and thereafter making the preliminary photoresist layer subject to patterning utilizing a photo mask. The second photoresist layer PR2 overlapping the groove GV may be formed through the patterning process.

Referring to FIG. 15B, the display panel manufacturing method of the present disclosure may include a step (e.g., act or task) of forming the connecting electrode CNEc by etching the first connecting electrode layer LL1a. The step (e.g., act or task) of etching the first connecting electrode layer LL1a may be performed through wet etching. A portion of the first connecting electrode layer LL1a that does not overlap the second photoresist layer PR2 (refer to FIG. 15A) may be etched and removed, and the first connecting electrode layer LL1a that overlaps the second photoresist layer PR2 and remains may form the connecting electrode CNEc. Thereafter, the second photoresist layer PR2 may be removed.

Referring to FIG. 15C, the display panel manufacturing method of the present disclosure may include a step (e.g., act or task) of forming, on the connecting electrode CNEc and the pixel defining layer PDLa, the intermediate layer IML and the second electrode EL2 (e.g., the cathode). The step (e.g., act or task) of forming the intermediate layer IML and the step (e.g., act or task) of forming the second electrode EL2 may each be performed through a deposition process. For example, the step (e.g., act or task) of forming the cathode EL2 may include a step (e.g., act or task) of depositing the cathode EL2 disconnected by the groove GV and connected with the first connecting electrode layer LL1a.

The intermediate layer IML may be subjected to patterning by the tip portion TPc of the connecting electrode CNEc, and a portion of the intermediate layer IML may be arranged at (e.g., in) the groove GV. A portion of the intermediate layer IML separated from the intermediate layer IML by the tip portion TPc of the connecting electrode CNEc may be defined as the first split pattern PP1a. The first split pattern PP1a may include the same material as the intermediate layer IML. The first split pattern PP1a may be concurrently (e.g., simultaneously) formed with the intermediate layer IML through one process.

The second electrode EL2 may be subjected to patterning by the tip portion TPc of the connecting electrode CNEc, and a portion of the second electrode EL2 may be arranged at (e.g., in) the groove GV. The second electrode EL2 may be connected with (e.g., brought into contact with) the first connecting electrode layer LL1a. For example, the end of the second electrode EL2 and a portion of the end of the first connecting electrode layer LL1a not being covered by the intermediate layer IML may be connected with (e.g., brought into contact with) each other at the tip portion TPc of the connecting electrode CNEc. The second electrode EL2 may be connected to the conductive pattern CP through the connecting electrode CNEc, and the conductive pattern CP may electrically connect the power supply voltage (e.g., the second drive voltage) ELVSS (refer to FIG. 4) and the second electrode EL2.

A portion of the second electrode EL2 separated from the second electrode EL2 by the tip portion TPc of the connecting electrode CNEc may be defined as the second split pattern PP2a. The second split pattern PP2a may include the same material as the second electrode EL2. The second split pattern PP2a may be concurrently (e.g., simultaneously) formed with the second electrode EL2 through one process. The first split pattern PP1a and the second split pattern PP2a may form the dummy patterns DMPc.

As described above, the groove may be defined at the display panel to disconnect the intermediate layer (e.g., the emission pattern) and the second electrode (e.g., the cathode) for each pixel. Accordingly, lateral leakage current may be reduced or eliminated. In addition, the second electrode may be connected with the power supply voltage through the conductive pattern. Accordingly, a power supply voltage drop (e.g., IR Drop) may be reduced or eliminated.

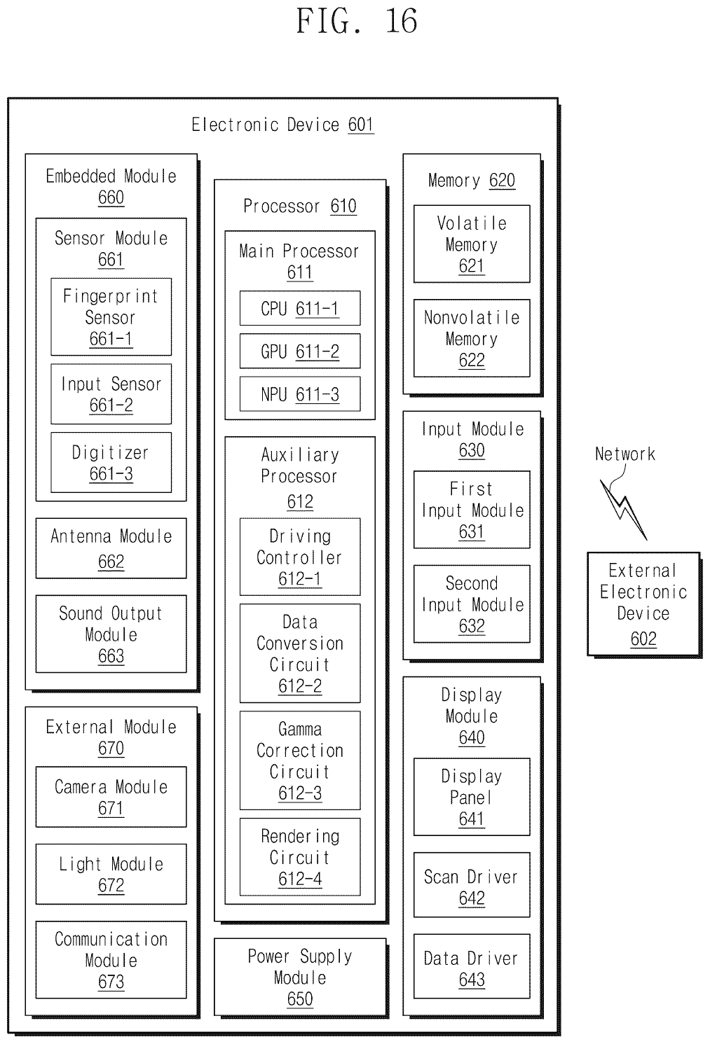

FIG. 16 is a block diagram of an electronic device, according to one or more embodiments of the present disclosure.

Referring to FIG. 16, an electronic device 601 outputs one or more suitable pieces of information through a display module 640 within an operating system. If (e.g., when) a processor 610 executes an application stored in a memory 620, a display module 640 provides application information to a user through a display panel 641.

The processor 610 obtains an external input through an input module 630 or a sensor module 661 and executes an application corresponding to the external input. For example, if (e.g., when) the user selects a camera icon displayed on the display panel 641, the processor 610 obtains a user input through an input sensor 661-2 and activates a camera module 671. The processor 610 delivers image data corresponding to a captured image obtained through the camera module 671 to the display module 640. The display module 640 may display an image corresponding to the captured image through the display panel 641.

For another example, if (e.g., when) personal information is authenticated on the display module 640, a fingerprint sensor 661-1 obtains entered fingerprint information as input data. The processor 610 compares input data obtained through the fingerprint sensor 661-1 with authentication data stored in the memory 620 and executes an application based on the comparison result. The display module 640 may display information, which is executed depending on the logic of the application, through the display panel 641.

For another example, if (e.g., when) a music streaming icon displayed on the display module 640 is selected, the processor 610 obtains a user input through the input sensor 661-2 and activates the music streaming application stored in the memory 620. If (e.g., when) a music play command is input by the music streaming application, the processor 610 provides sound information corresponding to the music play command to the user by activating a sound output module 663.

The operation of the electronic device 601 has been briefly described above. Hereinafter, a configuration of the electronic device 601 will be described in more detail. Some of components of the electronic device 601, which will be described in more detail, may be integrated and provided as one configuration, or the one configuration may be provided to be separated into two or more configurations.

Referring to FIG. 16, the electronic device 601 may communicate with an external electronic device 602 through a network (e.g., a short-range wireless communication network or a long-range wireless communication network). According to one or more embodiments, the electronic device 601 may include the processor 610, the memory 620, the input module 630, the display module 640, a power supply module 650, an embedded module 660, and an external module 670. According to one or more embodiments, in the electronic device 601, at least one of the above-described components may not be provided, or one or more other components may be added. According to one or more embodiments, some (e.g., the sensor module 661, an antenna module 662, or the sound output module 663) of the components described above may be integrated into another component (e.g., the display module 640).

The processor 610 may execute software to control at least another component (e.g., hardware or software component) of the electronic device 601 connected to the processor 610, and may process and calculate one or more suitable types (kinds) of data. According to one or more embodiments, as at least part of data processing or calculation, the processor 610 may store instructions or data received from other components (e.g., the input module 630, the sensor module 661 or a communication module 673) into a volatile memory 621, may process instructions or data stored in the volatile memory 621. The result data may be stored in a nonvolatile memory 622.

The processor 610 may include a main processor 611 and an auxiliary processor 612. The main processor 611 may include one or more of a central processing unit (CPU) 611-1 or an application processor (AP). The main processor 611 may further include one or more of a graphic processing unit (GPU) 611-2, a communication processor, and an image signal processor (ISP). The main processor 611 may further include a neural processing unit (NPU) 611-3. The NPU 611-3 may be a processor that is specialized in processing an artificial intelligence model. The artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, and/or a (e.g., any suitable) combination of two or more of the networks, but may not be limited thereto. In addition to a hardware structure, additionally or alternatively, the artificial intelligence model may include a software structure. At least two of the processing units and the processors that are described above may be implemented as one integrated component (e.g., a single chip) or may be implemented as independent components (e.g., a plurality of chips).

The auxiliary processor 612 may include a driving controller 612-1. The driving controller 612-1 may include an interface converting circuit and a timing control circuit. The driving controller 612-1 receives an image signal from the main processor 611, converts the data format of the image signal so as to be suitable for the interface specifications with the display module 640, and outputs image data. The driving controller 612-1 may output one or more suitable control signals desired or required to drive the display module 640.

The auxiliary processor 612 may further include a data converting circuit 612-2, a gamma correcting circuit 612-3, and a rendering circuit 612-4. The data converting circuit 612-2 may receive the image data from the driving controller 612-1 and may compensates for the image data such that an image is displayed at a desired or suitable luminance according to characteristics of the electronic device 601 or setting of the user or may convert the image data to reduce power consumption or compensate for afterimages. The gamma correcting circuit 612-3 may convert the image data, a gamma reference voltage, and/or the like such that the image displayed on the electronic device 601 has desired or suitable gamma characteristics. The rendering circuit 612-4 may receive the image data from the driving controller 612-1 and may render the image data in consideration of a pixel arrangement of the display panel 641 applied to the electronic device 601. At least one of the data converting circuit 612-2, the gamma correcting circuit 612-3, and the rendering circuit 612-4 may be integrated into another component (e.g., the main processor 611 or the driving controller 612-1). At least one of the data converting circuit 612-2, the gamma correcting circuit 612-3, and the rendering circuit 612-4 may be integrated into a data driver 643.

The memory 620 may store one or more suitable pieces of data, which are utilized by at least one component (e.g., the processor 610 or the sensor module 661) of the electronic device 601 and input data or output data for commands related thereto. The memory 620 may include at least one or more of the volatile memory 621 and the nonvolatile memory 622.

The input module 630 may receive, from the outside (e.g., the user or an external electronic device 602) of the electronic device 601, commands or data to be utilized in a component (e.g., the processor 610, the sensor module 661, and/or the sound output module 663) of the electronic device 601.

The input module 630 may include a first input module 631, through which the commands or data are input from the user, and a second input module 632 through which the commands or data are input from the external electronic device 602. The first input module 631 may include a microphone, a mouse, a keyboard, a key (e.g., a button), and/or a pen (e.g., a passive pen and/or an active pen). The second input module 632 may support a designated protocol capable of being connected to the external electronic device 602 by wire or wireless. According to one or more embodiments, the second input module 632 may include a high definition multimedia interface (HDMI), a universal serial bus (USB) interface, a secure digital (SD) card interface, and/or an audio interface. The second input module 632 may include a connector that may be physically connected to the external electronic device 602, for example, an HDMI connector, a USB connector, an SD card connector, and/or an audio connector (e.g., a headphone connector).

The display module 640 provides visual information to the user. The display module 640 may include the display panel 641, a scan driver 642, and the data driver 643. The display module 640 may further include a window, a chassis, a bracket, and/or the like for protecting the display panel 641. The display module 640 may further include a light-emitting driver, a voltage generator, and/or the like. The voltage generator may output one or more suitable voltages (e.g., the first and second driving voltages ELVDD and ELVSS (see FIG. 4)) desired or required to drive the display panel 641.

The power supply module 650 supplies power to the components of the electronic device 601. The power supply module 650 may include a battery that charges a power voltage. The battery may include a non-rechargeable primary cell, a rechargeable secondary cell, a fuel cell, and/or the like. The power supply module 650 may include a power management integrated circuit (PMIC). The PMIC supplies improved or optimized power to the above-described modules and modules which will be described in more detail. The power supply module 650 may include a wireless power transmission/reception member electrically connected to the battery. The wireless power transmission/reception member may include a plurality of coil-shaped antenna radiators.

The electronic device 601 may further include the embedded module 660 and the external module 670. The embedded module 660 may include the sensor module 661, the antenna module 662, and the sound output module 663. The external module 670 may include the camera module 671, a light module 672, and the communication module 673.

The sensor module 661 may detect an input from the user's body or an input from a pen among the first input module 631, and may generate an electrical signal or data value corresponding to the input. The sensor module 661 may include at least one of the fingerprint sensor 661-1, the input sensor 661-2, and/or a digitizer 661-3.

The fingerprint sensor 661-1 may generate a data value corresponding to a fingerprint of the user. The fingerprint sensor 661-1 may include one of an optical-type (kind) fingerprint sensor, and/or a capacitance-type (kind) fingerprint sensor.

The input sensor 661-2 may generate a data value corresponding to coordinate information of an input by a body of the user and/or an input by a pen. The input sensor 661-2 generates the change in capacitance due to the input as the data value. The input sensor 661-2 may sense an input by a passive pen or may be to transmit or receive data to and/or from an active pen.

The input sensor 661-2 may also measure a biometric signal such as blood pressure, moisture, and/or body fat. For example, if (e.g., when) the user touches a part of the body to a sensor layer and/or sensing panel and does not move during a specific period, the input sensor 661-2 may detect the biometric signal and may output information desired or suitable by the user to the display module 640 based on a changes in electric fields caused by the part of the body.

The digitizer 661-3 may generate the data value corresponding to coordinate information of an input by the pen. The digitizer 661-3 generates an electromagnetic change amount due to the input as the data value. The digitizer 661-3 may sense input by the passive pen and/or transmit or receive data to or from the active pen.

At least one of the fingerprint sensor 661-1, the input sensor 661-2, and the digitizer 661-3 may be implemented as a sensor layer formed on the display panel 641 through a subsequent process. The fingerprint sensor 661-1, the input sensor 661-2, and the digitizer 661-3 may be placed on the upper side of the display panel 641, and one (e.g., the digitizer 661-3) of the fingerprint sensor 661-1, the input sensor 661-2, and the digitizer 661-3 may be placed on the lower side of the display panel 641. At least two or more of the fingerprint sensor 661-1, the input sensor 661-2,

and the digitizer 661-3 may be formed to be integrated into one sensing panel through substantially the same process. If (e.g., when) being integrated into one sensing panel, the sensing panel may be placed between the display panel 641 and a window placed on the upper side of the display panel 641. According to one or more embodiments, the sensing panel may be placed on a window, and the location of the sensing panel is not particularly limited thereto.

At least one of the fingerprint sensor 661-1, the input sensor 661-2, and the digitizer 661-3 may be built into the display panel 641. For example, at least one of the fingerprint sensor 661-1, the input sensor 661-2, and the digitizer 661-3 may be concurrently (e.g., simultaneously) formed through a process of forming elements (e.g., a light-emitting element, a transistor, and/or the like) included in the display panel 641.

Besides, the sensor module 661 may generate an electrical signal or a data value corresponding to the internal state or external state of the electronic device 601. For example, the sensor module 661 may further include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illumination sensor.

The antenna module 662 may include one or more antennas to transmit or receive the signal or power to or from an external source. According to one or more embodiments, the communication module 673 may be to transmit or receive the signal to or from the external electronic device 602 through the antenna suitable for a communication method. An antenna pattern of the antenna module 662 may be integrated into the input sensor 661-2 or one component (e.g., the display panel 641) of the display module 640.

The sound output module 663 may be a device for outputting an audio signal to the outside of the electronic device 601 and, for example, may include a speaker utilized for general purposes, such as multimedia playback or recording playback, and a receiver utilized only for receiving a call. According to one or more embodiments, the receiver may be implemented separately from the speaker or may be integrated with the speaker. A sound output pattern of the sound output module 663 may be integrated into the display module 640.

The camera module 671 may shoot a still image or a video image. According to one or more embodiments, the camera module 671 may include one or more lenses, an image sensor, or an image signal processor. The camera module 671 may further include an infrared camera capable of measuring the presence or absence of the user, a position of the user, a gaze of the user, and/or the like.

The light module 672 may provide light. The light module 672 may include a light-emitting diode or a xenon lamp. The light module 672 may operate in conjunction with the camera module 671 or may operate independently from the camera module 671.

The communication module 673 may support establishing a wired or wireless communication channel between the electronic device 601 and the external electronic device 602 and performing communication through the established communication channel. The communication module 673 may include one or all of wireless communication modules such as a cellular communication module, a short-range wireless communication module, and/or a global navigation satellite system (GNSS) communication module, and/or wired communication modules such as a local area network (LAN) communication module and/or a power line communication module. The communication module 673 may communicate with the external electronic device 602 through a short-range communication network such as Bluetooth, WiFi direct, and/or infrared data association (IrDA), a long-range communication network such as a cellular network, Internet, and/or a computer network (e.g., the LAN or a wide area network (WAN)). The above-mentioned one or more suitable communication modules 673 may be implemented into one chip or may be respectively implemented into separate chips.

The input module 630, the sensor module 661, the camera module 671, and/or the like may be utilized to control an operation of the display module 640 in conjunction with the processor 610.

The processor 610 outputs commands and/or data to the display module 640, the sound output module 663, the camera module 671, and/or the light module 672 based on input data received from the input module 630. For example, the processor 610 may generate image data in response to input data applied through a mouse, an active pen, and/or the like to output the generated image data to the display module 640 or may generate command data in response to the input data to output the generated command data to the camera module 671 or the light module 672. If (e.g., when) no input data is received from the input module 630 during a specific period, the processor 610 may switch an operation mode of the electronic device 601 to a low-power mode and/or a sleep mode to reduce power consumed in the electronic device 601.

The processor 610 outputs commands and/or data to the display module 640, the sound output module 663, the camera module 671, and/or the light module 672 based on sensing data received from the sensor module 661. For example, the processor 610 may compare authentication data authorized by the fingerprint sensor 661-1 with the authentication data stored in the memory 620, and then may execute an application depending on the comparison result. The processor 610 may execute commands or may output corresponding image data to the display module 640 based on sensing data sensed by the input sensor 661-2 or the digitizer 661-3. If (e.g., when) the sensor module 661 includes a temperature sensor, the processor 610 receives temperature data regarding the measured temperature from the sensor module 661 and may further perform luminance correction on image data based on the temperature data.

The processor 610 may receive measurement data regarding the presence or absence of the user, the user's location, and the user's gaze from the camera module 671. The processor 610 may further perform luminance correction on the image data based on the measurement data. For example, the processor 610 that determines the presence or absence of the user through an input from the camera module 671 may output image data, of which the luminance is corrected, to the display module 640 through the data converting circuit 612-2 and/or the gamma correcting circuit 612-3.

Some of the components may be connected to each other through communication methods between peripheral devices, for example, a bus, a general purpose input/output (GPIO), a serial peripheral interface (SPI), a mobile industry processor interface (MIPI), and/or an ultra-path interconnect (UPI) link and may exchange a signal (e.g., commands or data) between each other. The processor 610 may communicate with the display module 640 through a mutually promised interface, and for example, may use any one of the above-described communication methods, and the present disclosure is not limited to the above-described communication methods.

In one or more embodiments, the electronic device 601 may be implemented with one or more suitable types (kinds) of devices. The electronic device 601 may include, for example, at least one of a portable communication device (e.g., a smart phone), a computer device, a portable multimedia device, a portable medical device, a camera, a wearable device, and/or a home appliance. The electronic device 601 according to one or more embodiments of the present application may not be limited to the above-described devices.

Overall, the thin film encapsulation layer of the display panel improves optical efficiency and also protects organic light-emitting diodes. Furthermore, an oxide semiconductor has high carrier mobility and low leakage current; therefore, such oxide semiconductor employed in the display panel may further reduce power consumption while preventing or reducing leakage current from flowing to the gate electrode of the display panel.

In the context of the present disclosure and unless otherwise defined, the terms “use/utilize,” “using/utilizing,” and “used/utilized” may be considered synonymous with the terms “utilize,” “utilizing,” and “utilized,” respectively.

A person of ordinary skill in the art would appreciate, in view of the present disclosure in its entirety, that each suitable feature of the one or more suitable embodiments of the present disclosure may be combined or combined with each other (or one another), partially or entirely, and may be technically interlocked and operated in one or more suitable ways, and each embodiment may be implemented independently of each other (or one another) or in conjunction with each other (or one another) in any suitable manner unless otherwise stated or implied.

The display apparatus/device, the electronic apparatus/device, the manufacturing apparatuses thereof, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In concluding the detailed description, those skilled in the art will appreciate that many variations and modifications may be made to one or more embodiments of the present application without substantially departing from the principles of disclosure. Therefore, the disclosed embodiments of present disclosure are utilized in a generic and descriptive sense only and not for purposes of limitation.

While the present disclosure has been described with reference to one or more embodiments thereof, it will be apparent to those of ordinary skill in the art that one or more suitable changes and modifications may be made thereto without departing from the spirit and scope of the present disclosure as set forth in the following claims and equivalents thereof. Moreover, it shall be appreciated that the one or more embodiments of the present disclosure are not intended to restrict the present disclosure thereto and that every technical idea within the appended claims and their equivalents is interpreted to be included in the scope of the present disclosure and equivalents thereof.

What is claimed is:

1. A display panel comprising:
a base layer;
a drive element layer on the base layer, the drive element layer comprising a pixel driver comprising a power supply voltage;
a conductive pattern at the drive element layer and electrically connected with the power supply voltage;
a pixel defining layer on the drive element layer, wherein a light-emitting opening and a groove configured to surround the light-emitting opening are defined at the pixel defining layer;
a light-emitting element on the pixel defining layer, the light-emitting element comprising a first electrode partially exposed by the light-emitting opening, an intermediate layer on the first electrode, and a second electrode on the intermediate layer and disconnected by the groove; and
a connecting electrode between the pixel defining layer and the second electrode and electrically connected with the conductive pattern and the second electrode.

2. The display panel of claim 1, wherein the connecting electrode comprises a first edge and a second edge configured to be around the first edge, and wherein the second edge overlaps the groove.

3. The display panel of claim 1, wherein the second electrode and the connecting electrode are connected at an area adjacent to the groove.

4. The display panel of claim 1, wherein the connecting electrode comprises a tip portion configured to protrude from an end of the groove, and
wherein the second electrode and the connecting electrode are connected at the tip portion.

5. The display panel of claim 4, wherein the connecting electrode further comprises a first connecting electrode layer on the pixel defining layer and a second connecting electrode layer on the first connecting electrode layer, and
wherein the second connecting electrode layer covers the first connecting electrode layer.

6. The display panel of claim 5, wherein the intermediate layer is on the second connecting electrode layer, and the second electrode is on the intermediate layer, and
wherein the second electrode is connected with the second connecting electrode layer at the tip portion.

7. The display panel of claim 5, wherein a first split pattern comprising the same material as the second connecting electrode layer, a second split pattern comprising the same material as the intermediate layer, and a third split pattern comprising the same material as the second electrode are at the groove.

8. The display panel of claim 7, wherein the first split pattern is electrically connected with the third split pattern.

9. The display panel of claim 4, wherein the connecting electrode further comprises a first connecting electrode layer on the pixel defining layer, and
wherein the intermediate layer covers the first connecting electrode layer, and the second electrode is connected with the first connecting electrode layer at the tip portion.

10. The display panel of claim 9, wherein a first split pattern comprising the same material as the intermediate layer and a second split pattern comprising the same material as the second electrode are at the groove.

11. The display panel of claim 1, wherein the pixel defining layer comprises a first pixel defining layer portion and a second pixel defining layer portion on the first pixel defining layer portion, and
wherein the first pixel defining layer portion is integrally provided with the second pixel defining layer portion, and the groove is defined in the second pixel defining layer portion.

12. The display panel of claim 1, wherein a through-hole is defined at the pixel defining layer, and the connecting electrode is connected to the conductive pattern through the through-hole.

13. The display panel of claim 1, wherein the light-emitting element comprises a plurality of light-emitting elements, the pixel driver comprises a plurality of pixel drivers, the connecting electrode comprises a plurality of connecting electrodes, and the plurality of light-emitting elements comprise a plurality of second electrodes disconnected from one another, and
wherein the plurality of second electrodes are connected to the conductive pattern through the plurality of connecting electrodes, respectively, and the conductive pattern is configured to electrically connect the power supply voltage with the plurality of second electrodes.

14. The display panel of claim 13, wherein a gap between connecting electrodes adjacent to each other among the plurality of connecting electrodes overlaps the groove.

15. A method comprising:
preparing a preliminary display panel comprising a base layer, a drive element layer on the base layer and comprising a pixel driver comprising a power supply voltage, a conductive pattern at the drive element layer and electrically connected with the power supply voltage, and a pixel defining layer on the drive element layer;
depositing, on the preliminary display panel, a first connecting electrode layer connected to the conductive pattern;
forming a groove of the pixel defining layer configured to overlap a portion of the first connecting electrode layer by etching a portion of the first connecting electrode layer and a portion of the pixel defining layer;
forming a connecting electrode by etching the first connecting electrode layer; and
forming, on the connecting electrode and the pixel defining layer, an intermediate layer and a cathode connected to the connecting electrode,
wherein the method is a method for manufacturing a display panel.

16. The method of claim 15, wherein the forming of the connecting electrode comprises forming a tip portion defined at an end of the first connecting electrode layer.

17. The method of claim 16, wherein the forming of the intermediate layer and the cathode connected to the connecting electrode comprises depositing the cathode disconnected by the groove and connected with the first connecting electrode layer.

18. The method of claim 15, further comprising:
depositing a second connecting electrode layer on the first connecting electrode layer; and
forming a tip portion defined at an end of the first connecting electrode layer and an end of the second connecting electrode layer,
wherein the forming of the connecting electrode comprises etching the second connecting electrode layer.

19. The method of claim 18, wherein the forming of the intermediate layer and the cathode connected to the connecting electrode comprises depositing the cathode disconnected by the groove and connected with the second connecting electrode layer.

20. An electronic device comprising:
a display panel for providing an image; and
a processor to control an operation of the display panel,
the display panel comprising:
a base layer;
a drive element layer on the base layer, the drive element layer comprising a pixel driver comprising a power supply voltage;
a conductive pattern at the drive element layer and electrically connected with the power supply voltage;
a pixel defining layer on the drive element layer, wherein a light-emitting opening and a groove configured to surround the light-emitting opening are defined at the pixel defining layer;
a light-emitting element on the pixel defining layer, the light-emitting element comprising a first electrode partially exposed by the light-emitting opening, an intermediate layer on the first electrode, and a second electrode on the intermediate layer and disconnected by the groove; and
a connecting electrode between the pixel defining layer and the second electrode and electrically connected with the conductive pattern and the second electrode.
